(19) United States
(12) Patent Application Publication
(10) Pub. No.: US 2024/0292670 A1
(43) Pub. Date: Aug. 29, 2024

(54) DISPLAY APPARATUS

(71) Applicant: SEMICONDUCTOR ENERGY LABORATORY CO., LTD., Atsugi-shi, Kanagawa-ken (JP)

(72) Inventors: Daiki NAKAMURA, Atsugi, Kanagawa (JP); Kenichi OKAZAKI, Atsugi, Kanagawa (JP); Rai SATO, Tochigi, Tochigi (JP)

(21) Appl. No.: 18/576,817

(22) PCT Filed: Jun. 27, 2022
(86) PCT No.: PCT/IB2022/055921

§ 371 Date: Jan. 5, 2024

(30) Foreign Application Priority Data
Jul. 8, 2021 (JP) 2021-113410

(51) Int. Cl. H10K 59/122

(52) U.S. Cl. CPC H10K 59/122

(57) ABSTRACT

A high-resolution or high-definition display apparatus is provided. The display apparatus includes a first light-emitting element and a second light-emitting element, in which the first light-emitting element and the second light-emitting element have a function of emitting light of different colors; the first light-emitting element includes a first pixel electrode, a first EL layer over the first pixel electrode, and a common electrode over the first EL layer; the second light-emitting element includes a second pixel electrode, a second EL layer over the second pixel electrode, and the common electrode over the second EL layer; the first EL layer includes a first layer over the first pixel electrode, and a first light-emitting layer over the first layer; the first layer includes a hole-injection layer; a region where an angle between a side surface of the first pixel electrode and a bottom surface of the first pixel electrode is greater than or equal to 60° and less than or equal to 140° is included; and a ratio (T1/T2) of a thickness T1 of the first pixel electrode with respect to a thickness T2 of a first layer is greater than or equal to 0.5.

### TECHNICAL FIELD

One embodiment of the present invention relates to a display apparatus, a display module, and an electronic device. One embodiment of the present invention relates to a method for manufacturing a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

In recent years, information terminal devices, for example, mobile phones such as smartphones, tablet information terminals, and laptop PCs (personal computers) have been widely used. As display panels provided in such devices, high-resolution display panels are required.

Examples of display apparatuses that can be used for a display panel include, typically, a liquid crystal display apparatus, a light-emitting apparatus including a light-emitting element such as an organic EL (Electro Luminescence) element or a light-emitting diode (LED), and electronic paper performing display by an electrophoretic method or the like.

For example, the basic structure of an organic EL element is a structure in which a layer containing a light-emitting organic compound is provided between a pair of electrodes. By applying voltage to this element, light emission can be obtained from the light-emitting organic compound. A display apparatus using such an organic EL element does not need a backlight that is necessary for a liquid crystal display device and the like: thus, a thin, lightweight, high-contrast, and low-power display apparatus can be achieved. Patent Document 1, for example, discloses an example of a display apparatus using an organic EL element.

### REFERENCE

### Patent Document

[Patent Document 1] Japanese Published Patent Application No. 2002-324673

### SUMMARY OF THE INVENTION

### Problems to be Solved by the Invention

An increase in pixel density with a reduction in pixel size sometimes causes problems that do not arise in a display having a large pixel size. One of such problems is an interference phenomenon of unintentional current flowing between adjacent pixels, that is, crosstalk.

In the case where a light-emitting element in which multiple light-emitting units are separated from each other by a charge-generation layer (hereinafter referred to as a tandem element) is used to manufacture a display, white light emission can be easily obtained; thus, a full-coloring method is achieved in many cases by employing the same EL layer structure for all pixels of a light-emitting element and by using a resonant structure or a color filter to emit light of expected color for each pixel.

Alternatively, without using a color filter or the like, full-color display can be achieved by a plurality of light-emitting elements emitting light of different colors. In this case, although pixels have different EL layer structures, a hole-injection layer, a hole-transport layer, an electron-injection layer, an electron-transport layer, and the like other than the light-emitting layer are each provided as a common layer in many cases.

A light-emitting element has a structure in which an EL layer is sandwiched between a pair of electrodes. In an active matrix light-emitting element, one of the pair of electrodes is divided for each pixel but the other electrode is formed so as to be shared by a plurality of pixels. Accordingly, the pixel is driven by controlling the one electrode divided for each pixel.

Here, when a plurality of light-emitting elements share part or all of the EL layer as a continuous common layer and the common layer has high conductivity, in some cases, current also flows between a first electrode of an element which is to be driven, and an electrode (second electrode) that is continuous and provided in the adjacent pixel, whereby crosstalk occurs.

In view of the above, an object of one embodiment of the present invention is to provide a light-emitting element in which occurrence of crosstalk can be suppressed. An object of one embodiment of the present invention is to provide a display apparatus in which occurrence of crosstalk is suppressed.

An object of one embodiment of the present invention is to provide a method for manufacturing a light-emitting element in which occurrence of crosstalk can be suppressed. An object of one embodiment of the present invention is to provide a method for manufacturing a display apparatus in which occurrence of crosstalk is suppressed.

An object of one embodiment of the present invention is to provide a high-resolution display apparatus. An object of one embodiment of the present invention is to provide a high-definition display apparatus. An object of one embodiment of the present invention is to provide a display apparatus with a high aperture ratio. An object of one embodiment of the present invention is to provide a large display apparatus. An object of one embodiment of the present invention is to provide a small display apparatus. An object of one embodiment of the present invention is to provide a highly reliable display apparatus.

An object of one embodiment of the present invention is to provide a method for manufacturing a high-resolution display apparatus. An object of one embodiment of the present invention is to provide a method for manufacturing a high-definition display apparatus. An object of one embodiment of the present invention is to provide a method for manufacturing a display apparatus with a high aperture ratio. An object of one embodiment of the present invention is to provide a method for manufacturing a large display apparatus. An object of one embodiment of the present invention is to provide a method for manufacturing a small display apparatus. An object of one embodiment of the present invention is to provide a method for manufacturing a highly reliable display apparatus. An object of one embodiment of the present invention is to provide a method for manufacturing a display apparatus with high yield.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display apparatus including a first light-emitting element and a second light-emitting element, in which the first light-emitting element and the second light-emitting element have a function of emitting light of different colors: the first light-emitting element includes a first pixel electrode, a first EL layer over the first pixel electrode, and a common electrode over the first EL layer: the second light-emitting element includes a second pixel electrode, a second EL layer over the second pixel electrode, and the common electrode over the second EL layer: the first EL layer includes a first layer over the first pixel electrode, and a first light-emitting layer over the first layer: the first layer includes a hole-injection layer: a region where an angle between a side surface of the first pixel electrode and a bottom surface of the first pixel electrode is greater than or equal to 60° and less than or equal to 140° is included; and a ratio (T1/T2) of a thickness T1 of the first pixel electrode with respect to a thickness T2 of the first layer in a region in contact with a top surface of the first pixel electrode is greater than or equal to 0.5.

One embodiment of the present invention is a display apparatus including a first insulating layer, a first light-emitting element over the first insulating layer, and a second light-emitting element over the first insulating layer, in which the first light-emitting element and the second light-emitting element have a function of emitting light of different colors: the first light-emitting element includes a first pixel electrode, a first EL layer over the first pixel electrode, and a common electrode over the first EL layer: the second light-emitting element includes a second pixel electrode, a second EL layer over the second pixel electrode, and the common electrode over the second EL layer: the first EL layer includes a first layer over the first pixel electrode, and a first light-emitting layer over the first layer: the first layer includes a hole-injection layer: the first insulating layer includes a depressed portion between the first pixel electrode and the second pixel electrode: a region where an angle between a bottom surface extension line extended, in parallel to a bottom surface of the first pixel electrode, from the lowest portion of the depressed portion to a region below the first pixel electrode is greater than or equal to 60° and less than or equal to 140° is included; and a ratio (ET/T2) of a shortest distance ET from the bottom surface extension line to a top surface of the first pixel electrode with respect to a thickness T2 of the first layer is greater than or equal to 0.5.

The display apparatus according to any one of the above preferably includes a second insulating layer in contact with the side surface of the first pixel electrode and a side surface of the second pixel electrode.

In the display apparatus according to any one of the above, the second insulating layer preferably contains an inorganic material.

The display apparatus according to any one of the above preferably includes a third insulating layer which is placed between the first pixel electrode and the second pixel electrode and below the common electrode.

In the display apparatus according to any one of the above, the third insulating layer preferably contains an organic material.

In the display apparatus according to any one of the above, the second EL layer includes a second layer over the second pixel electrode, and a second light-emitting layer over the second layer: between the first light-emitting element and the second light-emitting element, the third insulating layer is placed below the common electrode, the second insulating layer is placed below the third insulating layer, and a first organic layer is placed below the second insulating layer; and the first organic layer, the first layer, and the second layer include the same material.

In the display apparatus according to any one of the above, preferably, a second organic layer and a third organic layer are provided over the first organic layer, the second organic layer includes the same material as the first light-emitting layer, and the third organic layer preferably includes the same material as the second light-emitting layer.

In the display apparatus according to any one of the above, a top surface of the first EL layer, a top surface of the second EL layer, and a top surface of the third insulating layer each preferably include a region in contact with the common electrode.

In the display apparatus according to any one of the above, the first layer preferably includes a hole-transport layer over the hole-injection layer.

The display apparatus according to any one of the above, the first EL layer preferably includes an electron-transport layer over the first light-emitting layer.

In the display apparatus according to any one of the above, the first EL layer preferably includes an electron-injection layer between the electron-transport layer and the common electrode.

### Effect of the Invention

With one embodiment of the present invention, a light-emitting element in which occurrence of crosstalk can be suppressed can be provided. With one embodiment of the present invention, a display apparatus in which crosstalk is suppressed can be provided.

With one embodiment of the present invention, a method for manufacturing a light-emitting element in which occurrence of crosstalk can be suppressed can be provided. With one embodiment of the present invention, a method for manufacturing a display apparatus in which crosstalk is suppressed can be provided.

With one embodiment of the present invention, a high-resolution display apparatus can be provided. With one embodiment of the present invention, a high-definition display apparatus can be provided. With one embodiment of the present invention, a display apparatus with a high aperture ratio can be provided. With one embodiment of the present invention, a large display apparatus can be provided. With one embodiment of the present invention, a small display apparatus can be provided. With one embodiment of the present invention, a highly reliable display apparatus can be provided.

With one embodiment of the present invention, a method for manufacturing a high-resolution display apparatus can be provided. With one embodiment of the present invention, a method for manufacturing a high-definition display apparatus can be provided. With one embodiment of the present invention, a method for manufacturing a display apparatus with a high aperture ratio can be provided. With one embodiment of the present invention, a method for manufacturing a large display apparatus can be provided. With one embodiment of the present invention, a method for manufacturing a small display apparatus can be provided. With one embodiment of the present invention, a method for manufacturing a highly reliable display apparatus can be provided. With one embodiment of the present invention, a method for manufacturing a display apparatus with high yield can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a display apparatus. FIG. 1B is a cross-sectional view illustrating an example of the display apparatus.

FIG. 2A to FIG. 2C are cross-sectional views each illustrating an example of a display apparatus.

FIG. 3A to FIG. 3C are cross-sectional views each illustrating an example of a display apparatus.

FIG. 4A to FIG. 4C are cross-sectional views each illustrating an examples of a display apparatus.

FIG. 5A and FIG. 5B are cross-sectional views each illustrating an examples of a display apparatus.

FIG. 6A and FIG. 6B are cross-sectional views each illustrating an example of a display apparatus.

FIG. 7A to FIG. 7F are cross-sectional views each illustrating an example of a display apparatus.

FIG. 8A to FIG. 8F are top views each illustrating an example of a pixel.

FIG. 9A and FIG. 9B are top views illustrating an example of a method for manufacturing a display apparatus.

FIG. 10A to FIG. 10C are cross-sectional views illustrating an example of a method for manufacturing a display apparatus.

FIG. 11A to FIG. 11C are cross-sectional views illustrating an example of a method for manufacturing a display apparatus.

FIG. 12A to FIG. 12C are cross-sectional views illustrating an example of a method for manufacturing a display apparatus.

FIG. 13A to FIG. 13C are cross-sectional views illustrating an example of a method for manufacturing a display apparatus.

FIG. 14A to FIG. 14C are cross-sectional views illustrating an example of a method for manufacturing a display apparatus.

FIG. 15A to FIG. 15F are diagrams each illustrating a structure example of a light-emitting element.

FIG. 16 is a perspective view illustrating an example of a display apparatus.

FIG. 17A is a cross-sectional view illustrating an example of a display apparatus. FIG. 17B and

FIG. 17C are cross-sectional views each illustrating an example of a transistor.

FIG. 18 is a cross-sectional view illustrating an example of a display apparatus.

FIG. 19 is a cross-sectional view illustrating an example of a display apparatus.

FIG. 20 is a cross-sectional view illustrating an example of a display apparatus.

FIG. 21A to FIG. 21D are cross-sectional views each illustrating an example of a display apparatus.

FIG. 22A and FIG. 22B are perspective views illustrating an example of a display module.

FIG. 23 is a cross-sectional view illustrating an example of a display apparatus.

FIG. 24 is a cross-sectional view illustrating an example of a display apparatus.

FIG. 25 is a cross-sectional view illustrating an example of a display apparatus.

FIG. 26 is a cross-sectional view illustrating an example of a display apparatus.

FIG. 27 is a cross-sectional view illustrating an example of a display apparatus.

FIG. 28A is a block diagram showing an example of a display apparatus. FIG. 28B to FIG. 28D are diagrams each showing an example of a pixel circuit.

FIG. 29A to FIG. 29D are cross-sectional views each illustrating an example of a transistor.

FIG. 30A and FIG. 30B are diagrams each illustrating an example of an electronic device.

FIG. 31A and FIG. 31B are diagrams each illustrating an example of an electronic device.

FIG. 32A is a diagram illustrating an example of an electronic device. FIG. 32B is a cross-sectional view illustrating an example of the electronic device.

FIG. 33A to FIG. 33D are diagrams illustrating examples of electronic devices.

FIG. 34A to FIG. 34G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

The position, size, range, or the like of each component illustrated in drawings does not represent the actual position, size, range, or the like in some cases for easy understanding. Thus, the disclosed invention is not necessarily limited to the position, size, range, or the like disclosed in the drawings.

The term “film” and the term “layer” can be interchanged with each other depending on the case or circumstances. For example, the term “conductive layer” can be replaced with the term “conductive film”. As another example, the term “insulating film” can be replaced with the term “insulating layer”.

Note that in this specification, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

Note that in this specification and the like, “parallel” indicates a state where two straight lines are placed at an angle of greater than or equal to −10° and less than or equal to 10°, for example. Accordingly, the case where the angle is greater than or equal to −5° and less than or equal to 5° is also included. Moreover, “perpendicular” and “orthogonal” indicate a state where two straight lines are placed at an angle of greater than or equal to 80° and less than or equal to 100°, for example. Accordingly, the case where the angle is greater than or equal to 85° and less than or equal to 95° is also included.

### Embodiment 1

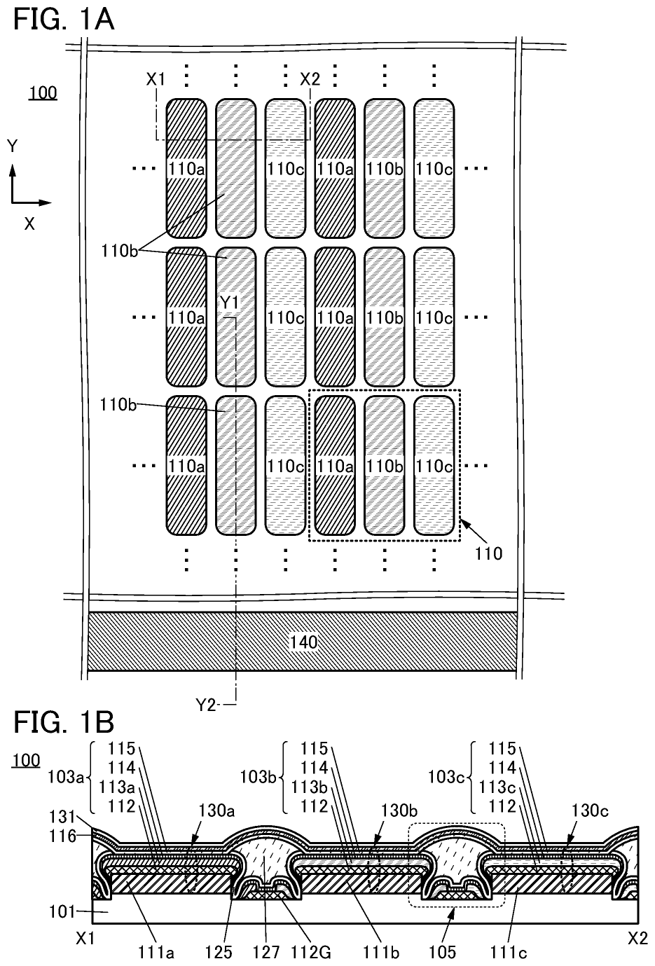

In this embodiment, a display apparatus of one embodiment of the present invention and a manufacturing method thereof are described with reference to FIG. 1 to FIG. 13.

In the display apparatus of one embodiment of the present invention, pixels are arranged in a matrix in a display portion, and an image can be displayed on the display portion. The pixels each include a plurality of subpixels emitting light of different colors: the plurality of subpixels include light-emitting layers different from each other and a common layer shared by the light emitting layers. With the common layer, the manufacturing process can be simplified and the manufacturing cost can be reduced.

Note that in this specification and the like, a pixel refers to one element whose brightness can be controlled, for example. For example, one pixel expresses one color element by which brightness is expressed. In the case of a color display apparatus having color elements of R(Red), G (Green), and B(Blue), a minimum unit of an image is composed of three pixels of an R pixel, a G pixel, and a B pixel. In that case, the pixel of each of RGB can also be referred to as a subpixel, and the three subpixels of RGB can be collectively referred to as a pixel. When a light-emitting device is used in accordance with each color in the subpixels of each pixel, full-color display can be performed.

As the light-emitting device, an OLED (Organic Light Emitting Diode) or a QLED (Quantum-dot Light Emitting Diode) can be preferably used, for example. Examples of a light-emitting substance contained in the light-emitting device include a substance emitting fluorescent light (a fluorescent material), a substance emitting phosphorescent light (a phosphorescent material), an inorganic compound (e.g., a quantum dot material), and a substance exhibiting thermally activated delayed fluorescence (a thermally activated delayed fluorescence (TADF) material).

In the case where a light-emitting device in each subpixel is formed of an EL device, an EL layer included in the EL device includes a light-emitting layer. The EL layer preferably includes any one or more of a hole-injection layer, a hole-transport layer, an electron-transport layer, and an electron-injection layer in addition to the light-emitting layer. In this case, the EL layers included in the subpixels can include different light-emitting layers, and some layers (a hole-injection layer, a hole-transport layer, an electron-injection layer, an electron-transport layer, and the like) as common layers. For example, in the case where a display apparatus includes three subpixels of RGB, the subpixel of R, the subpixel of G, and the subpixel of B include a first EL layer, a second EL layer, and a third EL layer, respectively: a first light-emitting layer included in the first EL layer, a second light-emitting layer included in the second EL layer, and a third light-emitting layer included in the third EL layer are formed of materials different from each other; and some layers in the EL layers (a hole-injection layer, a hole-transport layer, an electron-injection layer, an electron-transport layer, and the like) can be formed of the same material as common layers. Note that the EL layer may include some layers (a hole-injection layer, a hole-transport layer, an electron-injection layer, an electron-transport layer, and the like) that are not formed as common layers.

In the case where light-emitting devices in subpixels are formed of EL devices emitting light of different colors, for the formation of the EL layers included in the EL devices, light-emitting layers are formed into island shapes with the use of a metal mask, and some layers in the EL layers (a hole-injection layer, a hole-transport layer, an electron-injection layer, an electron-transport layer, and the like) can be formed as common layers. However, some layers included in the EL layer have relatively high conductivity: when a layer having high conductivity is shared by the pixels, leakage current might be generated between the pixels. Particularly when an increase in resolution or aperture ratio of a display apparatus reduces the distance between pixels, the leakage current might become too large to ignore and cause, for example, a decrease in display quality of the display apparatus. In view of the above, in the display apparatus according to one embodiment of the present invention, at least some layers in the EL layer in each pixel are formed into island shapes to achieve increased resolution and reliability of the display apparatus.

In a method for manufacturing a display apparatus of one embodiment of the present invention, after a conductive layer is formed over the entire surface, a resist mask is formed in a position corresponding to each pixel, and the conductive layer is processed into an island shape, so that a first electrode (also referred to as a lower electrode of a light-emitting element) is formed. At this time, a step with a height T1 is formed in a region positioned between adjacent first electrodes. Next, one layer in an EL layer is formed over the entire surface. The one layer in the EL layer formed here can be referred to as a first layer. Here, a region in which the first layer is not formed can be obtained at the side surface of the first electrode under the following condition: when an angle between the side surface of the first electrode and the bottom surface of the first electrode is a taper angle θ, and the thickness of the first layer is T2, the T1/T2 is set to greater than or equal to 0.5, preferably greater than or equal to 0.8, further preferably greater than or equal to 1, and still further preferably greater than or equal to 1.5, and θ is greater than or equal to 60° and less than or equal to 140°, preferably greater than or equal to 70° and less than or equal to 140°, and further preferably greater than or equal to 80° and less than or equal to 140°. In this case, since the first layer is divided into island shapes at the same position as the first electrodes, the first layer of each pixel can be separately formed in a self-aligned manner. Note that in the case where the insulating layer positioned below the first electrode is etched to include a step portion having a concave shape (a depressed portion) between the adjacent first electrodes, the height T1 of the step between the adjacent first electrodes is the sum of the thickness of the first electrode and the depth of a step portion of the insulating layer. Note that the first layer preferably includes a carrier-injection layer (a hole-injection layer or an electron-injection layer) and further preferably includes a carrier-transport layer (a hole-transport layer or an electron-transport layer) 20) in addition to the carrier-injection layer between the first layer and the light-emitting layer.

As described above, a region of the side surface of the island-shaped electrode where upper layers are not formed is sometimes referred to as a disconnection portion or a disconnection region. Note that as described above, a region where the first layer is not formed (a disconnection portion) is preferably included at the side surface of the first electrode: however, an effect of electrically isolating the first layer of each pixel can be sometimes obtained also by setting the thickness of the first layer to be small. Thus, a region where the first layer is not formed does not have to be included at the side surface of the first electrode.

Next, the light-emitting layer is formed over the first layer of each pixel. For example, in the case where a display apparatus includes three subpixels of RGB in one pixel, a light-emitting layer emitting red light, a light-emitting layer emitting green light, and a light-emitting layer emitting blue light are formed. The light-emitting layer can be formed, for example, by an evaporation method using a metal mask. Alternatively, the light-emitting layer may be formed by an ink-jet method. The light-emitting layer may have a region where the light-emitting layer is not formed at the side surface of the island-shaped first electrode like the first layer: the light-emitting layer may be formed in the region. Furthermore, a region in which the light-emitting layers emitting light of different colors overlap with each other may be provided between the adjacent first electrodes.

Next, a second layer is formed as one layer in the EL layer over the entire surface. For example, in the case where a hole-injection layer and a hole-transport layer are formed as the first layers, an electron-transport layer is formed as the second layer. For another example, in the case where the electron-injection layer and the electron-transport layer are formed as the first layers, a hole-transport layer is formed as the second layer. The second layer may be divided into island shapes like the first layer, but is not necessarily divided into island shapes.

Next, an insulating layer is formed over the entire surface. After that, the insulating layer is processed so as to leave the insulating layer in a depressed portion between the adjacent first electrodes. At this time, the side surface of the first electrode may include a first region directly in contact with the first layer and a second region directly in contact with the insulating layer. Note that the insulating layer may include one layer but preferably includes two or more layers. In the case where the insulating layer includes two or more layers, an insulating layer formed first and an insulating layer formed next can be represented as a first insulating layer and a second insulating layer, respectively, with the use of an ordinal number. For example, in the case where the insulating layer includes two layers, a material having high solvent resistance, a high barrier property against moisture, and a high gas barrier property is used as a material of the first insulating layer, whereby damage caused to the EL layer in a manufacturing process of the display apparatus can be reduced, and the reliability of the light-emitting device can be increased. Furthermore, in the formation of the second insulating layer, a liquid material is used to fill the depressed portion between the adjacent pixels, in which case a planar shape can be easily obtained.

Subsequently, the insulating layer is removed in a position where the first electrode, the first layer, the light-emitting layer, the second layer, and the insulating layer overlap with each other, so that the second layer is exposed. Then, a second electrode (sometimes referred to as an upper electrode of a light-emitting element) is formed so as to be in contact with at least the exposed portion of the EL layer of each pixel. Here, in the case where the depressed portion between the adjacent pixels is filled with an insulating layer, the second electrode can be formed without disconnection at the depressed portion between the adjacent pixels, whereby a defect such as disconnection of the second electrode can be inhibited. Note that a third layer may be formed before the formation of the second electrode. An electron-injection layer or a hole-injection layer, for example, can be formed as the third layer. Moreover, an electron-transport layer and an electron-injection layer, or a hole-transport layer and a hole-injection layer may be formed as the third layers.

In this manner, in the method for manufacturing a display apparatus of one embodiment of the present invention, when the first layer is deposited as one layer in an EL layer over the entire surface, the first layer is separately formed in a self-aligned manner in a position of the lower electrode (the first electrode). Thus, a light-emitting element capable of inhibiting generation of crosstalk can be obtained. In addition, a high-resolution display apparatus or a display apparatus with a high aperture ratio, which has been difficult to achieve, can be manufactured. Furthermore, when a depressed portion between adjacent pixels is filled with the insulating layer, a defect such as disconnection at the time of the formation of the upper electrode of the EL layer can be suppressed, so that productivity and reliability of a light-emitting device can be increased. As described above, for the island-shaped EL layer, the periphery of the EL layer which is not in contact with the upper electrode and the lower electrode is covered with the material having high solvent resistance, a high barrier property against moisture, and a high gas barrier property; accordingly, the damage caused to the EL layer in the manufacturing process of the display apparatus is reduced, whereby the reliability of the light-emitting device can be increased.

In this specification and the like, a device manufactured using a metal mask or an FMM (fine metal mask, high-resolution metal mask) may be referred to as a device having an MM (metal mask) structure. In this specification and the like, a device manufactured without using a metal mask or an FMM may be referred to as a device having an MML (metal maskless) structure.

Note that in the light-emitting device, it is not necessary to form all layers included in the EL layer to have island shapes, and some of the layers can be deposited in the same step. In the method for manufacturing a display apparatus of one embodiment of the present invention, some of the layers included in the EL layer are formed to have island shapes in each pixel, and then, some of the above-described insulating layers (sometimes referred to as a protective insulating layer or a barrier layer) is removed, and the other layer(s) included in the EL layer (e.g., a carrier-injection layer) and a common electrode (also referred to as an upper electrode) can be formed in common.

Meanwhile, the carrier-injection layer is often a layer having relatively high conductivity in the light-emitting device. Thus, when the carrier-injection layer is in contact with the side surface of the island-shaped EL layer, the light-emitting device might be short-circuited. Note that also in the case where the carrier-injection layer is formed into an island shape and only the common electrode is formed to be shared by light-emitting devices, the light-emitting device might be short-circuited when the common electrode is in contact with the side surface of the island-shaped EL layer or the side surface of the pixel electrode. In view of such concern, in the display apparatus of one embodiment of the present invention, the insulating layer (the first insulating layer and the second insulating layer) covering the side surface of the island-shaped EL layer (e.g . . . the light-emitting layer) and the side surface of the pixel electrode is included. This can inhibit at least some layers of the island-shaped EL layers and the pixel electrodes from being in contact with the carrier-injection layer or the common electrode. Thus, a short circuit in the light-emitting device is inhibited, and the reliability of the light-emitting device can be increased. Note that in some cases, the carrier-injection layer is included in and referred to as a common electrode.

The display apparatus of one embodiment of the present invention includes a pixel electrode functioning as an anode: a hole-injection layer, a hole-transport layer, a light-emitting layer, and an electron-transport layer that are provided in this order over the pixel electrode: an insulating layer provided so as to cover the side surfaces of the pixel electrode, the hole-injection layer, the hole-transport layer, the light-emitting layer, and the electron-transport layer: an electron-injection layer provided over the electron-transport layer; and a common electrode that is provided over the electron-injection layer and functions as a cathode. Here, at least the pixel electrode and the hole-injection layer are provided into island shapes.

Alternatively, the display apparatus of one embodiment of the present invention includes a pixel electrode functioning as a cathode: an electron-injection layer, an electron-transport layer, a light-emitting layer, and a hole-transport layer that are provided in this order over the pixel electrode: an insulating layer provided so as to cover the side surfaces of the pixel electrode, the electron-injection layer, the electron-transport layer, the light-emitting layer, and the hole-30) transport layer: a hole-injection layer provided over the hole-transport layer; and a common electrode that is provided over the hole-injection layer and functions as an anode. Here, at least the pixel electrode and the electron-injection layer are provided into island shapes.

Alternatively, the display apparatus of one embodiment of the present invention includes a pixel electrode, a first light-emitting unit over the pixel electrode, an intermediate layer (also referred to as a charge-generation layer) over the first light-emitting unit, a second light-emitting unit over the intermediate layer, an insulating layer provided so as to cover the side surfaces of the pixel electrode, the first light-emitting unit, the intermediate layer, and the second light-emitting unit, and a common electrode provided over the second light-emitting unit. Note that a layer common to light-emitting devices of different colors may be provided between the second light-emitting unit and the common electrode. Here, at least the pixel electrode and the first light-emitting unit are provided into island shapes.

The hole-injection layer, the electron-injection layer, and the charge-generation layer, for example, often have relatively high conductivity in the EL layer. Since the side surfaces of these layers are covered with the insulating layer in the display apparatus of one embodiment of the present invention, these layers can be inhibited from being in contact with the common electrode or the like. Thus, a short circuit in the light-emitting device is inhibited, and the reliability of the light-emitting device can be increased.

The display apparatus of one embodiment of the present invention includes an insulating layer that covers the side surface of the pixel electrode, the side surface of the first layer, the side surface of the light-emitting layer, and the side surface of the second layer. In the manufacturing process of the display apparatus, the first layer can be separately formed in a self-aligned manner; accordingly, one embodiment of the present invention is a method for manufacturing a display apparatus with reduced number of manufacturing steps and a low manufacturing cost. In addition, the insulating layer inhibits the pixel electrode from being in contact with a carrier-injection layer or a common electrode, thereby inhibiting a short circuit in the light-emitting device.

The insulating layer included between adjacent pixel electrodes may have a single-layer structure or a stacked-layer structure. An insulating layer having a two-layer structure is particularly preferably used. For example, the first insulating layer is preferably formed using an inorganic insulating material because it is formed in contact with the EL layer. In particular, the first insulating layer is preferably formed by an atomic layer deposition (ALD) method, by which damage due to deposition is small. Alternatively, an inorganic insulating layer is preferably formed by a sputtering method, a chemical vapor deposition (CVD) method, or a plasma-enhanced chemical vapor deposition (PECVD) method, which have higher deposition speed than an ALD method. In that case, a highly reliable display apparatus can be manufactured with high productivity. In addition, the second insulating layer is preferably formed using an organic material so that the depressed portion between the adjacent pixels is planarized.

For example, an aluminum oxide film formed by an ALD method can be used as the first insulating layer, and a photosensitive organic resin film can be used as the second insulating layer.

### Structure Example 1 of Display Apparatus

FIG. 1A and FIG. 1B illustrate a display apparatus of one embodiment of the present invention.

FIG. 1A illustrates a top view of a display apparatus 100. The display apparatus 100 includes a display portion in which a plurality of pixels 110 are arranged in a matrix, and a connection portion 140 outside the display portion.

The pixels 110 illustrated in FIG. 1A employ stripe arrangement. Each of the pixels 110 illustrated in FIG. 1A is made up of three subpixels 110a, 110b, and 110c. The subpixels 110a, 110b, and 110c respectively include a light-emitting device 130a emitting red light, a light-emitting device 130b emitting green light, and a light-emitting device 130c emitting blue light (hereinafter, they may be collectively referred to as a light-emitting device 130).

FIG. 1B is a cross-sectional view taken along dashed-dotted line X1-X2 in FIG. 1A.

In FIG. 1, the subpixel 110a, the subpixel 110b, and the subpixel 110c include the light-emitting device 130a emitting red light, the light-emitting device 130b emitting green light, and the light-emitting device 130c emitting blue light, respectively. Note that the structure of the subpixels 110a, 110b, and 110c is not limited to three colors of red (R), green (G), and blue (B) and may be subpixels of three colors of yellow (Y), cyan (C), and magenta (M), for example.

FIG. 1A illustrates an example in which subpixels of different colors are arranged in the X direction and subpixels of the same color are arranged in the Y direction. Note that subpixels of different colors may be arranged in the Y direction and subpixels of the same color may be arranged in the X direction.

Although the top view of FIG. 1A illustrates an example in which the connection portion 140 is positioned in the lower side of the display portion, one embodiment of the present invention is not limited thereto. The connection portion 140 only needs to be provided in at least one of the upper side, the right side, the left side, or the lower side of the display portion in the top view, or may be provided so as to surround the four sides of the display portion. The number of the connection portions 140 can be one or more.

As illustrated in FIG. 1B, in the display apparatus 100, light-emitting devices 130a, 130b, and 130c are provided over a layer 101 including transistors, and a protective layer 131 is provided to cover these light-emitting devices.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The layer 101 including transistors can employ a stacked-layer structure in which a plurality of transistors are provided over a substrate and an insulating layer is provided so as to cover these transistors, for example. The layer 101 including transistors may have a depressed portion between adjacent light-emitting devices. For example, an insulating layer positioned on the outermost surface of the layer 101 including transistors may have a depressed portion. Structure examples of the layer 101 including transistors will be described later in Embodiments 3 and 4.

Each of the light-emitting devices includes an EL layer between a pair of electrodes. In this specification and the like, one of the pair of electrodes may be referred to as a pixel electrode and the other may be referred to as a common electrode.

One of the pair of electrodes of the light-emitting device functions as an anode, and the other electrode functions as a cathode. Hereinafter, the case where the pixel electrode functions as an anode and the common electrode functions as a cathode is described as an example.

The light-emitting device 130a includes a pixel electrode 111a over the layer 101 including transistors, an island-shaped first layer 112 over the pixel electrode 111a, a first light-emitting layer 113a over the first layer 112, a second layer 114 over the first light-emitting layer 113a, a third layer 115 over the second layer 114, and a common electrode 116 over the third layer 115. In the light-emitting device 130a, the first layer 112, the first light-emitting layer 113a, the second layer 114, and the third layer 115 can be collectively referred to as an EL layer 103a. Note that structure examples of the light-emitting device will be described later in Embodiment 2.

The light-emitting device 130b includes a pixel electrode 111b over the layer 101 including transistors, the island-shaped first layer 112 over the pixel electrode 111b, a second light-emitting layer 113b over the first layer 112, the second layer 114 over the second light-emitting layer 113b, the third layer 115 over the second layer 114, and the common electrode 116 over the third layer 115. In the light-emitting device 130b, the first layer 112, the second light-emitting layer 113b, the second layer 114, and the third layer 115 can be collectively referred to as an EL layer 103b.

The light-emitting device 130c includes a pixel electrode 111c over the layer 101 including transistors, the island-shaped first layer 112 over the pixel electrode 111c, a third light-emitting layer 113c over the first layer 112, the second layer 114 over the third light-emitting layer 113c, the third layer 115 over the second layer 114, and the common electrode 116 over the third layer 115. In the light-emitting device 130c, the first layer 112, the third light-emitting layer 113c, the second layer 114, and the third layer 115 can be collectively referred to as an EL layer 103c.

The EL layer 103a included in the light-emitting device 130a, the EL layer 103b included in the light-emitting device 130b, and the EL layer 103c included in the light-emitting device 130c are collectively referred to as an EL layer 103. Furthermore, the first light-emitting layer 113a included in the light-emitting unit 130a, the second light-emitting layer 113b included in the light-emitting device 130b, and the third light-emitting layer 113c included in the light-emitting device 130c are collectively referred to as a light-emitting layer 113 in some cases.

The light-emitting devices of the respective colors share the same film as the common electrode 116. The common electrode shared by the light-emitting devices is electrically connected to a conductive layer provided in the connection portion 140. Thus, the same potential is supplied to the common electrode included in the light-emitting devices.

A conductive film that transmits visible light is used as the electrode through which light is extracted, which is either the pixel electrode or the common electrode. A conductive film that reflects visible light is preferably used as the electrode through which light is not extracted.

As a material that forms the pair of electrodes (the pixel electrode and the common electrode) of the light-emitting device, a metal, an alloy, an electrically conductive compound, a mixture thereof, and the like can be used as appropriate. Specific examples include indium tin oxide (In—Sn oxide, also referred to as ITO), In—Si—Sn oxide (also referred to as ITSO), indium zinc oxide (In—Zn oxide), In—W—Zn oxide, an alloy containing aluminum (an aluminum alloy) such as an alloy of aluminum, nickel, and lanthanum (Al—Ni—La), and an alloy of silver, palladium, and copper (Ag—Pd—Cu, also referred to as APC). In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting devices preferably employ a microcavity structure. Accordingly, one of the pair of electrodes of the light-emitting device preferably includes an electrode having a transmitting property and a reflecting property with respect to visible light (a semi-transmissive and semi-reflective electrode), and the other is preferably an electrode having a reflecting property with respect to visible light (a reflective electrode). When the light-emitting device has a microcavity structure, light obtained from the light-emitting layer can be resonated between the electrodes, whereby light emitted from the light-emitting device can be intensified.

Note that the semi-transmissive and semi-reflective electrode can have a stacked-layer structure of a reflective electrode and an electrode having a transmitting property with respect to visible light (also referred to as a transparent electrode).

The transparent electrode has a light transmittance higher than or equal to 40%. For example, an electrode having a visible light (light with a wavelength greater than or equal to 400 nm and less than 750 nm) transmittance higher than or equal to 40% is preferably used in the light-emitting device. The semi-transmissive and semi-reflective electrode has a visible light reflectance of higher than or equal to 10% and lower than or equal to 95%, and preferably higher than or equal to 30% and lower than or equal to 80%. The reflective electrode has a visible light reflectance of higher than or equal to 40% and lower than or equal to 100%, and preferably higher than or equal to 70% and lower than or equal to 100%. These electrodes preferably have a resistivity less than or equal to 1× Ω⁻² cm.

The first layer 112 is provided into an island shape over the pixel electrode 111 (111a, 111b, and 111c) of each pixel. The EL layer 103a, the EL layer 103b, and the EL layer 103c each include the light-emitting layer 113 (113a, 113b, and 113c).

The light-emitting layer is a layer containing a light-emitting substance. The light-emitting layer can contain one or more kinds of light-emitting substances. Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton: an organometallic complex (particularly an iridium complex) having a phenylpyridine derivative including an electron-withdrawing group as a ligand: a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting device can be achieved at the same time.

In addition to the light-emitting layer, the EL layer 103a, the EL layer 103b, and the EL layer 103c may further include a layer containing any of a substance with a high hole-injection property, a substance with a high hole-transport property, a hole-blocking material, a substance with a high electron-transport property, a substance with a high electron-injection property, an electron-blocking material, a substance with a bipolar property (a substance with a high electron-transport property and a high hole-transport property), and the like.

Either a low molecular compound or a high molecular compound can be used for the light-emitting device, and an inorganic compound may also be contained. Each layer included in the light-emitting device can be formed by an evaporation method (including a vacuum evaporation method), a sputtering method, a printing method, an inkjet method, a coating method, or the like.

For example, the first layer 112 may include a hole-injection layer or an electron-injection layer. The first layer 112 may further include not only the hole-injection layer or the electron-injection layer but also a hole-transport layer or an electron-transport layer. For example, in the case where the pixel electrode 111 is an anode, the first layer 112 can be a hole-injection layer, or a hole-injection layer and a hole-transport layer. For another example, in the case where the pixel electrode 111 is a cathode, the first layer 112 can be an electron-injection layer, or an electron-injection layer and an electron-transport layer.

The light-emitting layer 113 (113a, 113b, and 113c) preferably includes a carrier-transport layer as the second layer 114 over the light-emitting layer 113. Accordingly, the light-emitting layer 113 is inhibited from being exposed on the outermost surface in the manufacturing process of the display apparatus 100, so that damage to the light-emitting layer 113 can be reduced. Thus, the reliability of the light-emitting device can be increased. For example, in the case where the pixel electrode 111 is an anode, the second layer 114 can be an electron-transport layer. For another example, in the case where the pixel electrode 111 is a cathode, the second layer 114 can be a hole transport layer.

In the EL layer 103, a carrier-injection layer (a hole-injection layer or an electron-injection layer) may be formed as the third layer 115 over the second layer 114. For example, in the case where the pixel electrode 111 is an anode, the third layer 115 can be an electron-injection layer. For another example, in the case where the pixel electrode 111 is a cathode, the third layer 115 can be a hole injection layer.

The hole-injection layer is a layer injecting holes from an anode to a hole-transport layer and containing a material with a high hole-injection property. Examples of a material with a high hole-injection property include an aromatic amine compound and a composite material containing a hole-transport material and an acceptor material (electron-accepting material).

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 10⁻⁶ cm²/Vs is preferable. Note that other substances can also be used as long as they have a property of transporting more holes than electrons. As the hole-transport material, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-transport layer is a layer transporting electrons, which are injected from a cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-transport layer may have a stacked-layer structure, and may include a hole-blocking layer, in contact with the light-emitting layer, which blocks holes moving from the anode side to the cathode side through the light-emitting layer.

The electron-injection layer is a layer injecting electrons from a cathode to the electron-transport layer and containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, it is possible to use, for example, an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ, where X is a given number), or cesium carbonate. The electron-injection layer may have a stacked-layer structure of two or more layers. In the stacked-layer structure, for example, lithium fluoride can be used for the first layer and ytterbium can be used for the second layer.

Alternatively, an electron-transport material may be used for the electron-injection layer. For example, a compound having an unshared electron pair and having an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), or 2,4,6-tris[3′-(pyridin-3-yl)biphenyl-3-yl]-1,3,5-triazine (abbreviation: TmPPPyTz) or the like can be used for the organic compound having an unshared electron pair. Note that NBPhen has a higher glass transition temperature (Tg) than BPhen and thus has high heat resistance.

In addition, in the case of manufacturing a light-emitting device having a tandem structure, an intermediate layer is provided between two light-emitting units. The intermediate layer has a function of injecting electrons into one of the two light-emitting units and injecting holes to the other when voltage is applied between the pair of electrodes.

For example, for the intermediate layer, a material that can be used for the electron-injection layer, such as lithium, can be suitably used. For another example, for the intermediate layer, a material that can be used for the hole-injection layer can be suitably used. A layer containing a hole-transport material and an acceptor material (electron-accepting material) can be used as the intermediate layer. A layer containing an electron-transport material and a donor material can be used as the intermediate layer. Forming the intermediate layer including such a layer can inhibit an increase in the driving voltage that would be caused by stacking light-emitting units.

The side surfaces of the pixel electrode 111, the first layer 112, the light-emitting layer 113, and the second layer 114 are covered with an insulating layer 125 and the insulating layer 127. Thus, the third layer 115 (and/or the common electrode 116) can be inhibited from being in contact with the side surface of any of the pixel electrode 111, the first layer 112, the light-emitting layer 113, and the second layer 114, whereby a short circuit of the light-emitting device can be inhibited.

In the case where the EL layer 103 (103a, 103b, and 103c) has a tandem structure, the side surfaces of a plurality of light-emitting units and intermediate layers included in these layers are also covered with the insulating layer 125 and the insulating layer 127. Hence, the third layer 115 (and/or the common electrode 116) can be inhibited from being in contact with the side surface of any of the plurality of light-emitting units or the intermediate layers, whereby a short circuit of the light-emitting device can be inhibited.

The insulating layer 125 preferably covers at least the side surface of the pixel electrode 111. Furthermore, the insulating layer 125 preferably covers the side surfaces of the first layer 112, the light-emitting layer 113, and the second layer 114. The insulating layer 125 can be in contact with the side surface(s) of any one or more of the pixel electrode 111 and the second layer 114. The insulating layer 125 is preferably an insulating layer containing an inorganic material.

The insulating layer 127 is provided over the insulating layer 125 so as to fill a depressed portion formed in the insulating layer 125. The insulating layer 127 can overlap with the side surfaces of the pixel electrode 111, the first layer 112, the light-emitting layer 113, and the second layer 114 with the insulating layer 125 therebetween. The insulating layer 127 is preferably an insulating layer containing an organic material. Note that the insulating layer 125 is provided below the insulating layer 127, and an organic layer 112G or the like is provided below the insulating layer 125. Providing the organic layer 112G or the like enables the shape of the insulating layer 127 after filling to be flatter in some cases.

Note that one of the insulating layer 125 and the insulating layer 127 is not necessarily provided. For example, in the case where the insulating layer 125 is not provided, the insulating layer 127 can be in contact with at least part of the side surface of the EL layer 103. The structure in which the insulating layer 125 or the insulating layer 127 is not provided can reduce the number of steps for manufacturing the display apparatus. Meanwhile, in the case where the insulating layer 125 containing an inorganic material is provided in contact with the side surfaces of the first layer 112, the light-emitting layer 113, and/or the second layer 114, the effect of inhibiting entry of impurities into these layers can be enhanced. Furthermore, providing the insulating layer 127 can improve the planarity of the formation surfaces of the third layer 115 and the common electrode 116.

The third layer 115 and the common electrode 116 are provided over the second layer 114, the insulating layer 125, and the insulating layer 127. At the stage before the insulating layer 125 and the insulating layer 127 are provided, a step is generated due to a region where the pixel electrode 111 is provided and a region where the pixel electrode 111 is not provided (a region between the light-emitting devices). The display apparatus of one embodiment of the present invention can planarize the step by including the insulating layer 125 and the insulating layer 127, whereby the coverage with the third layer 115 and the common electrode 116 can be improved. Consequently, it is possible to inhibit a connection defect due to disconnection of the common electrode 116. Alternatively, it is possible to inhibit an increase in electric resistance due to local thinning of the common electrode 116 by the step. Note that in some cases, the third layer 115 is included in and referred to as the common electrode 116.

In order to improve the planarity of the formation surfaces of the third layer 115 and the common electrode 116, the top surface of the insulating layer 125 and the top surface of the insulating layer 127 are each preferably level or substantially level with the top surface of at least one of the first layer 112, the light-emitting layer 113, and the second layer 114. In addition, the top surface of the insulating layer 127 preferably has a flat shape and may have a projection portion or a depressed portion.

The insulating layer 125 has a region in contact with the side surface(s) of any one or more of the first layer 112, the light-emitting layer 113, and the second layer 114 and functions as a protective insulating layer of the first layer 112, the light-emitting layer 113, and the second layer 114. Providing the insulating layer 125 can inhibit impurities (e.g., oxygen and moisture) from entering the inside of the first layer 112, the light-emitting layer 113, and the second layer 114 through their side surfaces, resulting in a highly reliable display apparatus.

When the width (thickness) of the insulating layer 125 in the region in contact with the side surface(s) of any one or more of the first layer 112, the light-emitting layer 113, and the second layer 114 is large in the cross-sectional view, the intervals between the first layer 112, the light-emitting layer 113, and the second layer 114 increase, so that the aperture ratio may be reduced. Meanwhile, a small width (thickness) of the insulating layer 125 may weaken the effect of inhibiting impurities from entering the inside of the first layer 112, the light-emitting layer 113, and/or the second layer 114 through their side surfaces. The width (thickness) of the insulating layer 125 in the region in contact with the side surface(s) of any one or more of the first layer 112, the light-emitting layer 113, and the second layer 114 is preferably greater than or equal to 3 nm and less than or equal to 200 nm, further preferably greater than or equal to 3 nm and less than or equal to 150 nm, further preferably greater than or equal to 5 nm and less than or equal to 150 nm, still further preferably greater than or equal to 5 nm and less than or equal to 100 nm, still further preferably greater than or equal to 10 nm and less than or equal to 100 nm, and yet further preferably greater than or equal to 10 nm and less than or equal to 50 nm. When the width (thickness) of the insulating layer 125 is within the above range, the display apparatus can have both a high aperture ratio and high reliability.

The insulating layer 125 can be an insulating layer containing an inorganic material. As the insulating layer 125, an inorganic insulating film such as an oxide insulating film, a nitride insulating film, an oxynitride insulating film, and a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the EL layer in etching and has a function of protecting the EL layer when the insulating layer 127 described later is formed. Specifically, when an inorganic insulating film such as an aluminum oxide film, a hafnium oxide film, or a silicon oxide film formed by an ALD method is used for the insulating layer 125, the insulating layer 125 having few pinholes and an excellent function of protecting the EL layer can be formed.

Note that in this specification and the like, an oxynitride insulator refers to a material that contains more oxygen than nitrogen, and a nitride oxide insulator refers to a material that contains more nitrogen than oxygen. For example, silicon oxynitride refers to a material in which an oxygen content is higher than a nitrogen content, and silicon nitride oxide refers to a material in which a nitrogen content is higher than an oxygen content.

The insulating layer 125 can be formed by a sputtering method, a CVD method, a PLD method, an ALD method, or the like. The insulating layer 125 is preferably formed by an ALD method achieving good coverage.

The insulating layer 127 provided over the insulating layer 125 has a function of filling the depressed portion of the insulating layer 125, which is formed between the adjacent light-emitting devices. In other words, the insulating layer 127 has an effect of improving the planarity of the formation surface of the common electrode 116. An insulating layer containing an organic material can be suitably used as the insulating layer 127. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used, for example. Alternatively, for the insulating layer 127, an organic material such as polyvinyl alcohol (PVA), polyvinyl butyral, polyvinylpyrrolidone, polyethylene glycol, polyglycerin, pullulan, water-soluble cellulose, an alcohol-soluble polyamide resin, or the like may be used. Alternatively, a photosensitive resin can be used for the insulating layer 127. A photoresist may be used as the photosensitive resin. As the photosensitive resin, a positive material or a negative material can be used.

A difference between the top surface level of the insulating layer 127 and the top surface level of the second layer 114 is, for example, preferably less than or equal to 0.5 times, and further preferably less than or equal to 0.3 times the thickness of the insulating layer 127. For another example, the insulating layer 127 may be provided such that the top surface level of the second layer 114 is higher than that of the insulating layer 127. For another example, the insulating layer 127 may be provided such that the top surface level of the insulating layer 127 is lower than that of the second layer 114.

The protective layer 131 is preferably included over the light-emitting devices 130a, 130b, and 130c. Providing the protective layer 131 can enhance the reliability of the light-emitting device.

Although the protective layer 131 is illustrated as one layer in FIG. 1B, the protective layer 131 may be a plurality of layers. For example, a two-layer structure of an inorganic layer and an inorganic layer, a two-layer structure of an inorganic layer and an organic layer, or a three-layer structure of an inorganic layer, an organic layer, and an inorganic layer may be employed.

There is no limitation on the conductivity of the protective layer 131. As the protective layer 131, at least one type of an insulating film, a semiconductor film, and a conductive film can be used.

When the protective layer 131 includes an inorganic film, it is possible to inhibit degradation of the light-emitting devices by preventing oxidation of the common electrode 116 or inhibiting entry of impurities (moisture, oxygen, and the like) into the light-emitting devices 130a, 130b, and 130c, for example: thus, the reliability of the display apparatus can be increased.

As the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

The protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 116. The inorganic film may further contain nitrogen.

When light emitted from the light-emitting device is extracted through the protective layer 131, the protective layer 131 preferably has a high transmitting property with respect to visible light. For example, ITO, IGZO, and aluminum oxide are preferable because they are inorganic materials having a high transmitting property with respect to visible light.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film.

The protective layer 131 may be formed by a plurality of different deposition methods. Specifically, the first layer of the protective layer 131 may be formed by an atomic layer deposition method, and the second layer of the protective layer 131 may be formed by a sputtering method.

Although not illustrated, a light-blocking layer may be provided in a position overlapping with the insulating layer between the pixels. Furthermore, a variety of optical members can be placed in a position overlapping with the light-emitting device. Examples of the optical members include a polarizing plate, a retardation plate, a light diffusion layer (a diffusion film or the like), an anti-reflective layer, and a light-condensing film. Furthermore, an antistatic film preventing the attachment of dust, a water repellent film suppressing the attachment of stain, a hard coat film suppressing generation of a scratch caused by the use, a shock absorption layer, or the like may be placed on the outer side of the display apparatus.

A substrate may be included over the protective layer 131 with a resin layer therebetween. For the substrate, glass, quartz, ceramic, sapphire, a resin, a metal, an alloy, a semiconductor, or the like can be used. The substrate on the side from which light from the light-emitting device is extracted is formed using a material that transmits the light. When a flexible material is used for the substrate, the flexibility of the display apparatus can be increased. Furthermore, a polarizing plate may be used as the substrate.

For the substrate, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, and still further preferably less than or equal to 10 nm.

Examples of the films having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of a display panel might be changed, e.g., creases are generated. Thus, for the substrate, a film with a low water absorption rate is preferably used. For example, the water absorption rate of the film is preferably lower than or equal to 1%, further preferably lower than or equal to 0.1%, and still further preferably lower than or equal to 0.01%.

For the above-described resin layer, a variety of curable adhesives, e.g., a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

Examples of materials that can be used for a gate, a source, and a drain of a transistor and conductive layers such as a variety of wirings and electrodes included in a display apparatus include metals such as aluminum, titanium, chromium, nickel, copper, yttrium, zirconium, molybdenum, silver, tantalum, or tungsten, and an alloy containing any of these metals as its main component. A film containing any of these materials can be used in a single layer or as a stacked-layer structure.

For a conductive material having a light-transmitting property, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the thickness is preferably set small enough to transmit light. Furthermore, a stacked film of any of the above materials can be used for the conductive layers. For example, a stacked film of indium tin oxide and an alloy of silver and magnesium, or the like is preferably used for increased conductivity. They can also be used for conductive layers such as wirings and electrodes included in the display apparatus, and conductive layers (e.g., a conductive layer functioning as a pixel electrode or a common electrode) included in a light-emitting device.

For an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

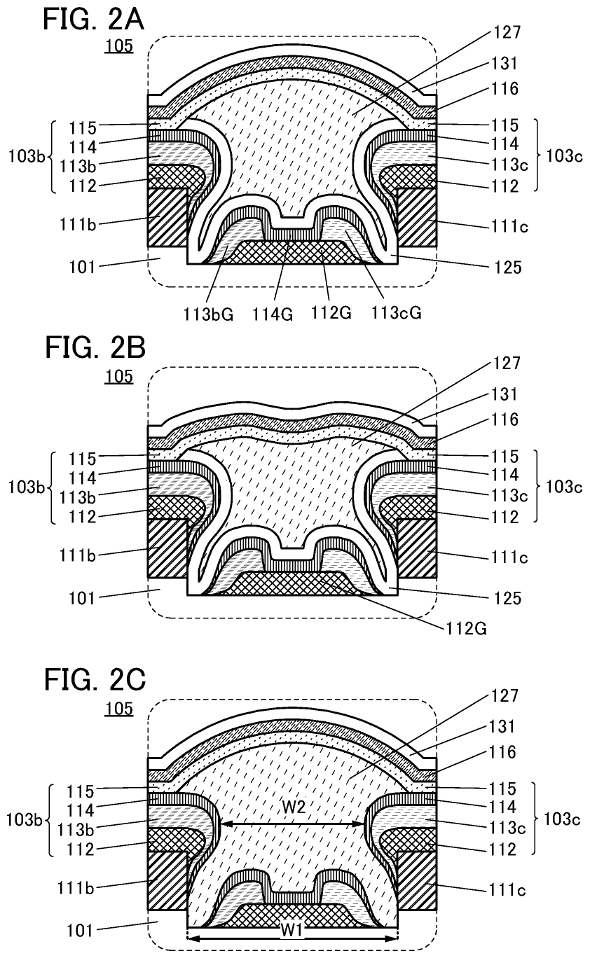

Next, modification examples and details of a cross-sectional shape of the display apparatus 100 are described with reference to FIG. 2 to FIG. 5. FIG. 2 to FIG. 5 illustrate enlarged views of a region 105 surrounded by dashed line in FIG. 1B to show the detailed structures and modification examples.

FIG. 2A is an enlarged view of the region 105 in FIG. 1B. In a schematic structural view illustrated in FIG. 2A, the side surface of the pixel electrode 111 (111b and 111c) includes a region in contact with the first layer 112 and a region in contact with the insulating layer 125. In addition, the surface of the pixel electrode 111 (111b and 111c) may include a region in contact with the light-emitting layer 113 (113b and 113c) and/or a region in contact with the second layer 114. An organic layer 112G, an organic layer 113bG, an organic layer 113cG, and an organic layer 114G are provided between the adjacent pixel electrodes. The first layer 112, the light-emitting layer 113 (113b and 113c), and the second layer 114 each have a region covered with the insulating layer 125 between the adjacent pixel electrode. The insulating layer 127 is provided over the insulating layer 125 between the adjacent pixel electrodes. The insulating layer 127 is preferably provided so as to fill the depressed portion between the adjacent pixel electrodes. As illustrated in FIG. 2A, the insulating layer 127 may have a curved projection portion between the adjacent pixel electrodes, and an end portion of the insulating layer 125 may have a forward tapered shape. In the case where the insulating layer 127 with a curved projection portion and the insulating layer 125 with a forward tapered end portion are included as described above, coverage with the third layer 115 and the common electrode 116 can be improved. Consequently, it is possible to inhibit a connection defect due to disconnection of the common electrode 116. Alternatively, it is possible to inhibit an increase in electric resistance due to local thinning of the common electrode 116 by a step. Note that although FIG. 2A illustrates an example in which the top surface of the insulating layer 127 has an arc-shaped projection portion in a cross-sectional view; part of the top surface of the insulating layer 127 may have a depressed portion as illustrated in FIG. 2B.

Although FIG. 2A illustrates a structure in which the insulating layer 125 is provided, the present invention is not limited thereto. FIG. 2C illustrates a modification example of the structure shown in FIG. 2A. As one embodiment of the present invention, the structure is allowable in which the insulating layer 125 is not provided as illustrated in FIG. 2C. In the case of the structure illustrated in FIG. 2C, an organic material that causes less damage to the first layer 112, the light-emitting layer 113, and the second layer 114 is preferably used for the insulating layer 127. For example, it is preferable to use, for the insulating layer 127, an organic material such as polyvinyl alcohol (PVA), polyvinyl butyral, polyvinyl pyrrolidone, polyethylene glycol, polyglycerin, pullulan, water-soluble cellulose, or alcohol-soluble polyamide resin.

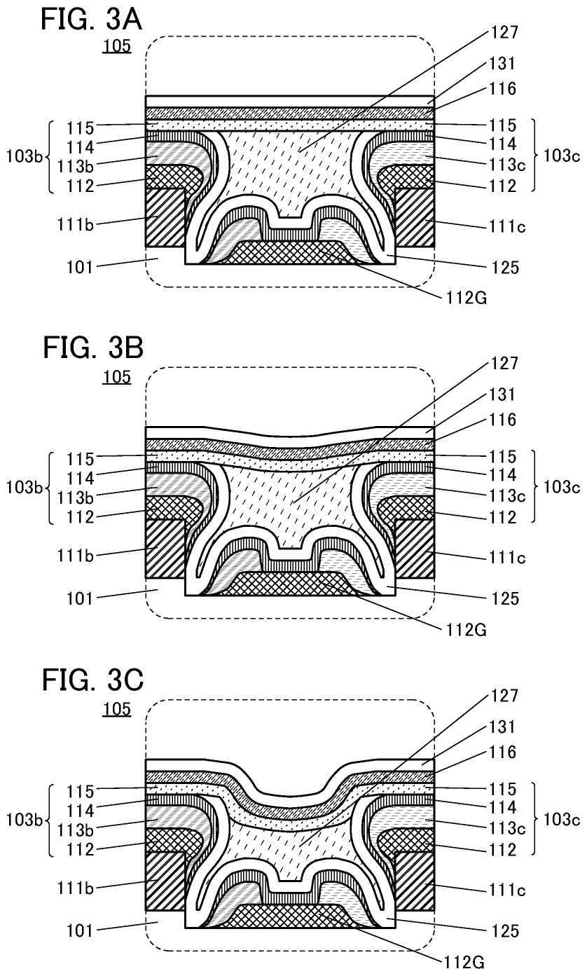

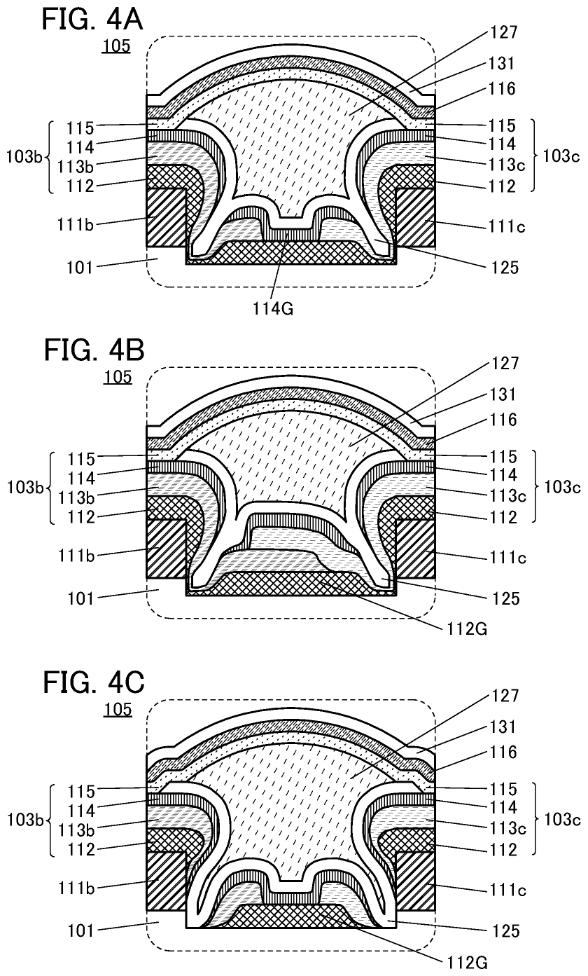

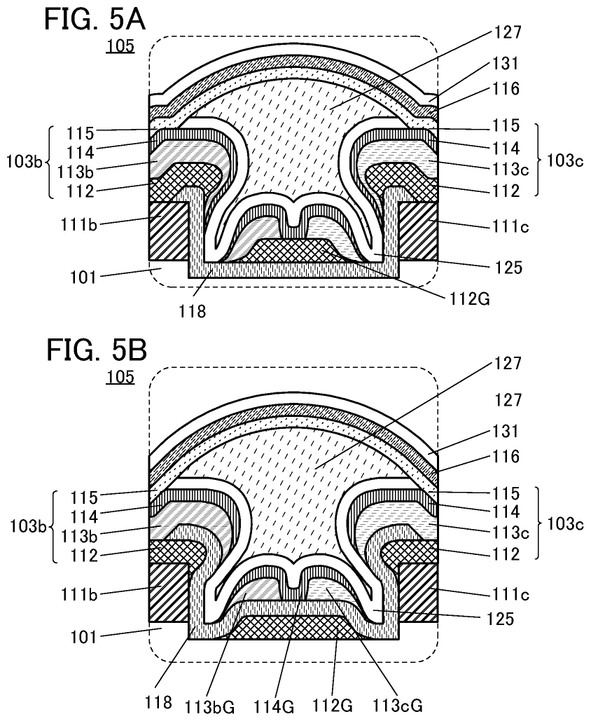

The shape of the insulating layer 127 of one embodiment of the present invention is described with reference to a width W1 of a first portion and a width W2 of a second portion indicated by double-headed arrows in FIG. 2C. The insulating layer 127 includes the first portion positioned between a pair of pixel electrodes and the second portion positioned between a pair of EL layers, and it can be said that the width W2 of the second portion is narrower than the width W1 of the first portion. In each of FIG. 2A, FIG. 2B, FIG. 3A to FIG. 3C, FIG. 4A to FIG. 4C, FIG. 5A, and FIG. 5B, the width W1 of the first portion and the width W2 of the second portion are not indicated: however, the insulating layer 127 includes the first portion positioned between the pair of pixel electrodes and the second portion positioned between the pair of EL layers, and the insulating layer 127 can be regarded as having a shape in which the width W2 of the second portion is narrower than the width W1 of the first portion, as in FIG. 2C. Note that the insulating layer 127 having a shape in which the width W2 of the second portion is narrower than the width W1 of the first portion is also said to have a constricted shape in a cross-sectional view.

Although FIG. 2A or the like illustrate a structure in which the top surface level of the insulating layer 125 and the top surface level of the insulating layer 127 are higher than the top surface level of the second layer 114, the present invention is not limited thereto. For example, as illustrated in FIG. 3A and FIG. 3B, the top surface of the insulating layer 125 and the top surface of the insulating layer 127 may be substantially level with the top surface of at least one of the first layer 112, the light-emitting layer 113, and the second layer 114.

Although FIG. 2A or the like illustrate an example of a structure where the layer 101 is etched between the adjacent pixel electrodes 111 (a structure in which the layer 101 includes a depressed portion between the adjacent pixel electrodes 111), the present invention is not limited thereto: a structure in which the layer 101 is not etched between the adjacent pixel electrodes 111 (a structure in which the layer 101 does not include a depressed portion between the adjacent pixel electrodes 111 or a structure in which the layer 101 between the adjacent pixel electrodes 111 is flat) may be employed. Note that the structure in which the layer 101 is etched between the adjacent pixel electrodes 111 can be described as a structure in which the layer 101 includes a step portion between the adjacent pixel electrodes 111: the step portion is referred to as a step portion of the layer 101.

Furthermore, as illustrated in FIG. 3C, the insulating layer 127 may have a depressed portion whose level is lower than the level of the top surface of at least one of the first layer 112, the light-emitting layer 113, and the second layer 114, in which case the third layer 115 and the common electrode 116 are desirably continuous at the depressed portion.

Note that although the side surface of the pixel electrode 111 preferably includes a region where the first layer 112 is not formed as described above, the effect of electrically isolating the light-emitting layers in the pixels can be obtained also by the thin thickness of the first layer 112 at the side surface of the pixel electrode 111 in some cases. Accordingly, the side surface of the pixel electrode 111 does not necessarily include the region where the first layer 112 is not formed.

Modification examples of the structure of the region 105 in this case are illustrated in FIG. 4A and FIG. 4B. FIG. 4A illustrates a modification example of the structure in FIG. 2A, in which the first layer 112 is formed to be thin at the side surface of the pixel electrode 111. FIG. 4B illustrates a state where in the structure of the region 105 in FIG. 1B, the first layer 112 is formed to be thin at the side surface of the pixel electrode 111, and furthermore, the light-emitting layer 113 (the second light-emitting layer 113b and the third light-emitting layer 113c) is formed to be thin and the second light-emitting layer 113b and the third light-emitting layer 113c overlap with each other over the organic layer 112G. In the display apparatus of one embodiment of the present invention, since the first layer 112 is disconnected or is thin between the adjacent pixel electrodes, crosstalk between the adjacent pixels can be inhibited even when the second light-emitting layer 113b and the third light-emitting layer 113c have a region overlapping with each other as illustrated in FIG. 4B.

FIG. 4C is a modification example of the structure illustrated in FIG. 2A. A structure in which the end portion of the insulating layer 125 is more on the outside than the insulating layer 127 as illustrated in FIG. 4C (also referred to as an apprentice structure) may be employed. When the curved top surface of the insulating layer 127 and the top surface of the insulating layer 125 are smoothly connected, the coverage with the third layer 115 and/or the common electrode 116 can be improved.

FIG. 5A and FIG. 5B are modification examples of the structure illustrated in FIG. 2A. A structure in which the insulating layer 118 is provided between the adjacent pixel electrodes 111 as illustrated in FIG. 5A may be employed.

As illustrated in FIG. 5A, in the case where the side surface of the pixel electrode 111 (111b and 111c) are covered with the insulating layer 118, the pixel electrode 111 (111b and 111c) and the light-emitting layer 113 (113b and 113c) can be prevented from being in contact with each other. It is also possible to prevent the pixel electrode 111 (111b and 111c) and the second layer 114 from being in contact with each other.

As illustrated in FIG. 5B, in the case where the side surfaces of the pixel electrode 111 (111b and 111c) and the first layer 112 are covered with the insulating layer 118, the pixel electrode 111 (111b and 111c) and the light-emitting layer 113 (113b and 113c) can be prevented from being in contact with each other. It is also possible to prevent the pixel electrode 111 (111b and 111c) and the second layer 114 from being in contact with each other. It is also possible to prevent the first layer 112 and the second layer 114 from being in contact with each other.

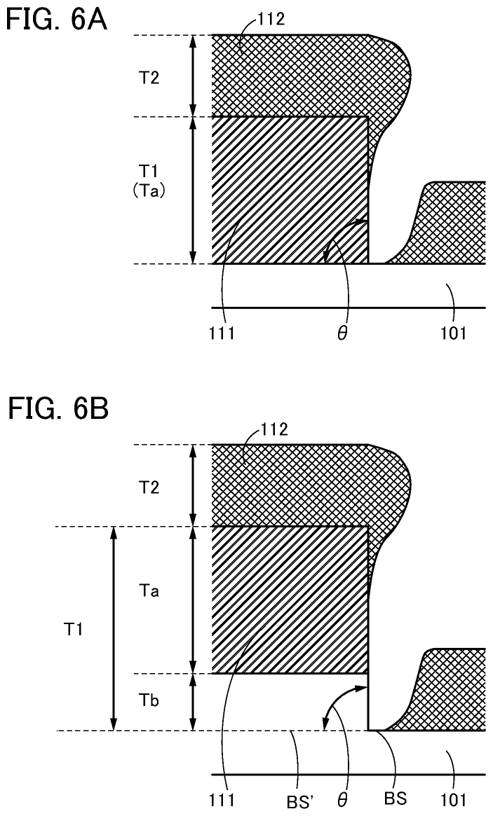

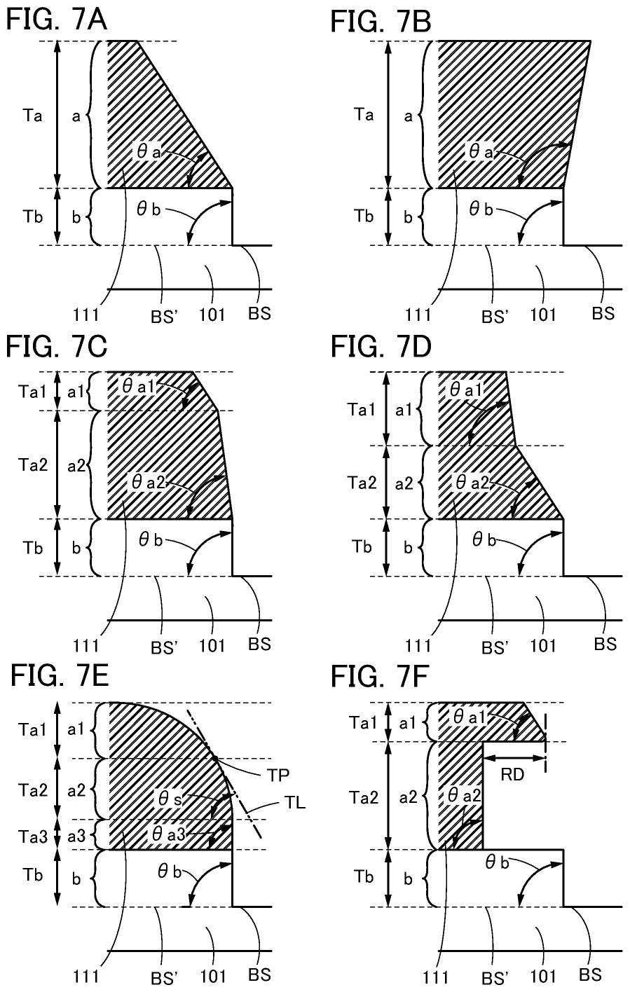

Next, a structure of a display apparatus of one embodiment of the present invention, in which the first layer 112 is separately formed in a self-aligned manner, is described with reference to FIG. 6A to FIG. 7F.

FIG. 6A and FIG. 6B are schematic cross-sectional views each illustrating a structure example of an end portion of the pixel electrode 111. Here, for description, only the layer 101, the pixel electrode 111, and the first layer 112 are illustrated. Note that details of the layer 101 are not illustrated.

In a method for manufacturing a display apparatus of one embodiment of the present invention, after a conductive layer is formed over the entire surface, a resist mask is formed in a position corresponding to the pixel, and the conductive layer is processed into an island shape, so that the pixel electrode 111 is formed. In FIG. 6A, an angle between the side surface of the pixel electrode 111 and the bottom surface of the pixel electrode 111 is a taper angle θ, and the thickness of the pixel electrode 111 is Ta. Since a step portion of the layer 101 is not formed in the example in FIG. 6A, a level difference T1 between the top surfaces of the layer 101 and the pixel electrode 111 matches the Ta.

Next, the first layer 112 is formed over the entire surface. Here, a region where the first layer 112 is not formed can be obtained at the side surface of the pixel electrode 111 under the following condition: when the thickness of the first layer 112 is T2, T1/T2 is greater than or equal to 0.5, preferably greater than or equal to 0.8, further preferably greater than or equal to 1, and still further preferably greater than or equal to 1.5 and θ is greater than or equal to 60° and less than or equal to 140°, preferably greater than or equal to 70° and less than or equal to 140°, and further preferably greater than or equal to 80° and less than or equal to 140°. In this case, since the first layer 112 is divided into island shapes at the same positions as the pixel electrodes 111, the first layer 112, the light-emitting layer 113, and the second layer 114 can be separately formed in a self-aligned manner.

FIG. 6B illustrates a modification example of FIG. 6A and is a diagram illustrating a structure where the layer 101 includes a step portion between the adjacent pixel electrodes 111. As illustrated in FIG. 6B, the height obtained by adding the thickness Ta of the pixel electrode 111 to a depth Tb of the step portion of the layer 101 is the level difference T1 (T1=Ta+Tb) of a step between the adjacent pixel electrodes 111. In FIG. 6B, an angle between a bottom surface extension line BS' extended from a bottom surface BS of the step portion of the layer 101 and the side surface of the step portion of the layer 101 is the taper angle θ. Note that in the case where the bottom surface BS of the step portion of the layer 101 and the bottom surface of the pixel electrode 111 are not parallel, an extension line extended, in parallel to the pixel electrode, from the lowest portion of the step portion of the layer 101 to a region below the pixel electrode 111 can be the bottom surface extension line BS′. Similarly, in the case where the bottom surface of the step portion of the layer 101 is not flat but curved, the extension line extended, in parallel to the pixel electrode, from the lowest portion of the step portion of the layer 101 to a region below the pixel electrode 111 can be the bottom surface extension line BS′. Thus, the level difference T1 can be described as the shortest distance from the bottom surface extension line BS' to the top surface of the first electrode. Here, a region where the first layer 112 is not formed can be obtained at the side surface of the pixel electrode 111 under the following condition: when the thickness of the first layer 112 is T2, T1/T2 is greater than or equal to 0.5, preferably greater than or equal to 0.8, further preferably greater than or equal to 1, and still further preferably greater than or equal to 1.5 and θ is greater than or equal to 60° and less than or equal to 140°, preferably greater than or equal to 70° and less than or equal to 140°, and further preferably greater than or equal to 80° and less than or equal to 140°. Thus, the structure in which the layer 101 is etched between the adjacent pixel electrodes 111 as illustrated in FIG. 6B can easily generate disconnection of the first layer 112.

As an example of the structure in which the layer 101 includes a step portion between the adjacent pixel electrodes 111, FIG. 6B illustrates a case where the side surface of the step portion of the layer 101 and the side surface of the pixel electrode 111 have the same taper angle and become a straight line in a cross-sectional view. The structure of the display apparatus of one embodiment of the present invention is not limited to the above structure, and the structure where the taper angle of the side surface of the step portion of the layer 101 and the taper angle of the side surface of the pixel electrode 111 are not equal to each other may be employed. Moreover, the side surface of the step portion of the layer 101 and/or the side surface of the pixel electrode 111 may have a plurality of surfaces or a curved surface. As these examples, FIG. 7A to FIG. 7F each illustrate a schematic cross-sectional view of the pixel electrode 111 and the step portion of the layer 101.

FIG. 7A and FIG. 7B each illustrate an example in which a taper angle θa of the side surface of the pixel electrode 111 and a taper angle θb of the side surface of the step portion of the layer 101 are not equal to each other. FIG. 7C and FIG. 7D each illustrate an example in which the side surface of the pixel electrode 111 has a plurality of surfaces. FIG. 7E illustrates an example in which the side surface of the pixel electrode 111 has a curved surface. FIG. 7F illustrates an example in which the side surface of the pixel electrode 111 is partly recessed. As described above, in order to divide the first layer 112 into island shapes in a self-aligned manner, the height of a step from the bottom surface of the step portion of the layer 101 to the top surface of the pixel electrode 111, the taper angle of the side surface of the step, and the thickness of the first layer 112 are each required to be within a predetermined range.

Here, an effective step height ET for dividing the first layer 112 into island shapes in a self-aligned manner is considered. Although not illustrated in FIG. 7A to FIG. 7F, the thickness of the first layer 112 is T2. In the case where the step portion of the layer 101 and the pixel electrode 111 are divided into a plurality of regions in accordance with the difference of taper angles, in FIG. 7A and FIG. 7B, for example, a region a has a height of Ta and a taper angle of da, and a region b has a height of Tb and a taper angle of θb. Here, a region where the first layer 112 is not formed can be obtained at the side surface of the pixel electrode 111 or the step portion of the layer 101, when ET/T2 is greater than or equal to 0.5, preferably greater than or equal to 0.8, further preferably greater than or equal to 1, and still further preferably greater than or equal to 1.5, where the effective step height ET refers to the value obtained by adding up the heights of regions each of which has a taper angle of greater than or equal to 60° and lower than or equal to 140°.

For example, in FIG. 7A, θa of the region a is less than 60° and θb of the region b is greater than or equal to 60° and less than or equal to 140°. Accordingly, ET=Tb is satisfied in the example illustrated in FIG. 7A. In FIG. 7B, θa of the region a and θb of the region b are each greater than or equal to 60° and less than or equal to 140°. Accordingly, ET=Ta+Tb is satisfied in the example illustrated in FIG. 7B.

In addition, in FIG. 7C, the pixel electrode 111 includes a region a1 and a region a2, and the step portion of the layer 101 includes the region b. θa1 of the region a1 is less than 60°, and θa2 of the region a2 and θb of the region b are each greater than or equal to 60° and less than or equal to 140°. Accordingly, ET=Ta2+Tb is satisfied in the example illustrated in FIG. 7C. In FIG. 7D, the pixel electrode 111 includes the region a1 and the region a2, and the step portion of the layer 101 includes the region b. θa1 of the region a1 and θb of the region b are each greater than or equal to 60° and less than or equal to 140°, and θa2 of the region a2 is less than 60°. Accordingly, ET=Ta1±Tb is satisfied in the example illustrated in FIG. 7D.

Note that in the case where the side surface of the pixel electrode 111 has a curved surface as illustrated in FIG. 7E, the effective step height ET includes the height of a region where an angle θs between a line parallel to the bottom surface of the pixel electrode 111 and a tangent TL on a point of contact TP of a curved line in a cross-sectional view of the curved surface is greater than or equal to 60° and less than or equal to 140°. In the case where the side surface of the pixel electrode 111 has a curved surface as in the example illustrated in FIG. 7E, the curved surface is considered to include the region a2 having an angle between the tangent of the curved line in a cross-sectional view and the bottom surface of the pixel electrode 111 of greater than or equal to 60° and less than or equal to 140° and the region a1 having an angle between the tangent and the bottom surface of the pixel electrode 111 of less than 60°. In this case, the pixel electrode 111 in FIG. 7E includes the region a1, the region a2, and a region a3. θs of the region a2, θa3 of the region a3, and the θb of the region b are each greater than or equal to 60° and less than or equal to 140°; accordingly, ET=Ta2+Ta3+Tb is satisfied.

Note that a taper angle (or an angle of the tangent) of a region whose height is included in the effective step height ET is preferably greater than or equal to 60° and less than or equal to 140° as described above. The taper angle is further preferably greater than or equal to 70° and less than or equal to 140°, and still further preferably greater than or equal to 80° and less than or equal to 140°.

In another example of the side surface of the pixel electrode 111 having a plurality of surfaces, the side surface of the pixel electrode 111 may be partly recessed as illustrated in FIG. 7F. Here, the thickness of a region in which a recessed distance RD is larger than 0 is included in the effective step height ET. In the example illustrated in FIG. 7F, θb of the region b is greater than or equal to 60° and less than or equal to 140°, the recessed distance RD of the region Ta2 is greater than 0, and θa1 of the region a1 is less than 60°; accordingly, ET=Ta2+Tb is satisfied. Note that the height of a region in which the recessed distance RD is greater than 0 can be included in the effective step height ET regardless of a taper angle of the region.

The structure illustrated in FIG. 7F can be formed when the pixel electrode 111 is composed of two layers formed using different materials (a first conductive layer and a second conductive layer) and the lower one of the conductive layers is formed using a material with a high etching rate, for example. More specifically, the structure can be formed in the following manner: at the time of the formation of the pixel electrode 111, the first conductive layer and the second conductive layer over the first conductive layer are subjected to anisotropic etching by a dry etching method or the like, and then the first conductive layer is selectively subjected to isotropic etching by a wet etching method or the like.

Note that the above-described region where the first layer 112 is not formed at the side surface of the pixel electrode 111 formed into the island shape or the step portion of the layer 101 is sometimes referred to as a disconnection portion or a disconnection region. Note that although the side surface of the pixel electrode 111 or the step portion of the layer 101 preferably includes the region where the first layer 112 is not formed as described above, the effect of electrically isolating the light-emitting layers in the pixels can be obtained also by the thin thickness of the first layer 112 at the side surface of the pixel electrode 111 or the side surface of the step portion of the layer 101 in some cases. Accordingly, the side surface of the pixel electrode 111 or the side surface of the step portion of the layer 101 does not necessarily include the region where the first layer 112 is not formed.

### [Pixel Layouts]

Next, pixel layouts different from that in FIG. 1A is described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and pentile arrangement.

Examples of a top surface shape of the subpixel include polygons such as a triangle, a tetragon (including a rectangle and a square), and a pentagon: polygons with rounded corners: an ellipse; and a circle. Here, the top surface shape of the subpixel corresponds to the top surface shape of a light-emitting region of the light-emitting device.

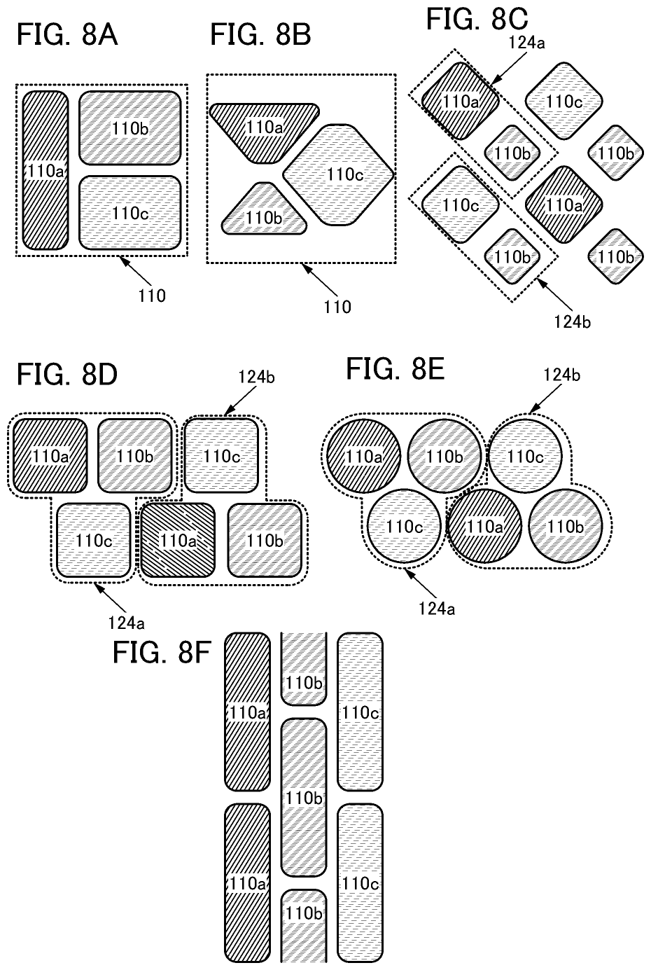

The pixel 110 illustrated in FIG. 8A employs S-stripe arrangement. The pixel 110 in FIG. 8A consists of three subpixels 110a, 110b, and 110c. For example, the subpixel 110a may be a blue subpixel B, the subpixel 110b may be a red subpixel R, and the subpixel 110c may be a green subpixel G.

The pixel 110 illustrated in FIG. 8B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110a has a larger light-emitting area than the subpixel 110b. In this manner, the shapes and sizes of the subpixels can be determined independently. For example, the size of a subpixel including a light-emitting device with higher reliability can be smaller. For example, the subpixel 110a may be the green subpixel G, the subpixel 110b may be the red subpixel R, and the subpixel 110c may be the blue subpixel B.

Pixels 124a and 124b illustrated in FIG. 8C employ pentile arrangement. FIG. 8C illustrates an example in which the pixels 124a including the subpixels 110a and the subpixels 110b and the pixels 124b including the subpixels 110b and the subpixels 110c are alternately arranged. For example, the subpixel 110a may be the red subpixel R, the subpixel 110b may be the green subpixel G, and the subpixel 110c may be the blue subpixel B.

The pixels 124a and 124b illustrated in FIG. 8D and FIG. 8E employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row). For example, the subpixel 110a may be the red subpixel R, the subpixel 110b may be the green subpixel G, and the subpixel 110c may be the blue subpixel B.

FIG. 8D illustrates an example in which the top surface of each subpixel has a rough tetragonal shape with rounded corners, and FIG. 8E illustrates an example in which the top surface of each subpixel has a circular shape.

FIG. 8F illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view. For example, the subpixel 110a may be the red subpixel R, the subpixel 110b may be the green subpixel G, and the subpixel 110c may be the blue subpixel B.

In a photolithography method, as a pattern to be formed by processing becomes finer, the influence of light diffraction becomes more difficult to ignore; accordingly, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel can have a polygonal shape with rounded corners, an elliptical shape, a circular shape, or the like.

The display apparatus of one embodiment of the present invention may include a light-receiving device in the pixel.

### Manufacturing Method Example of Display Apparatus

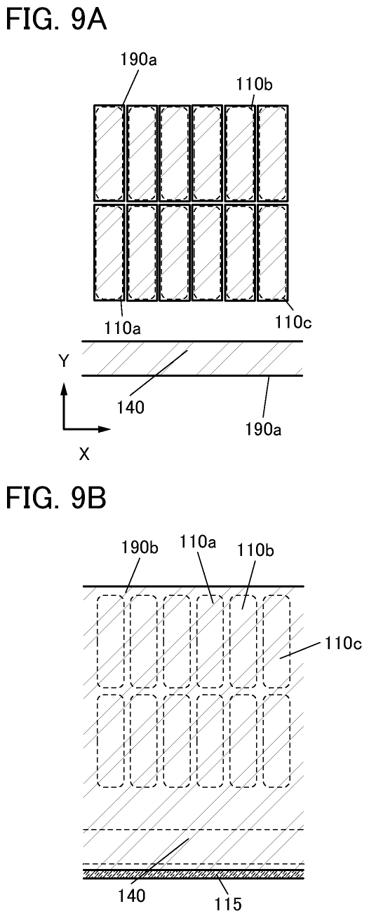

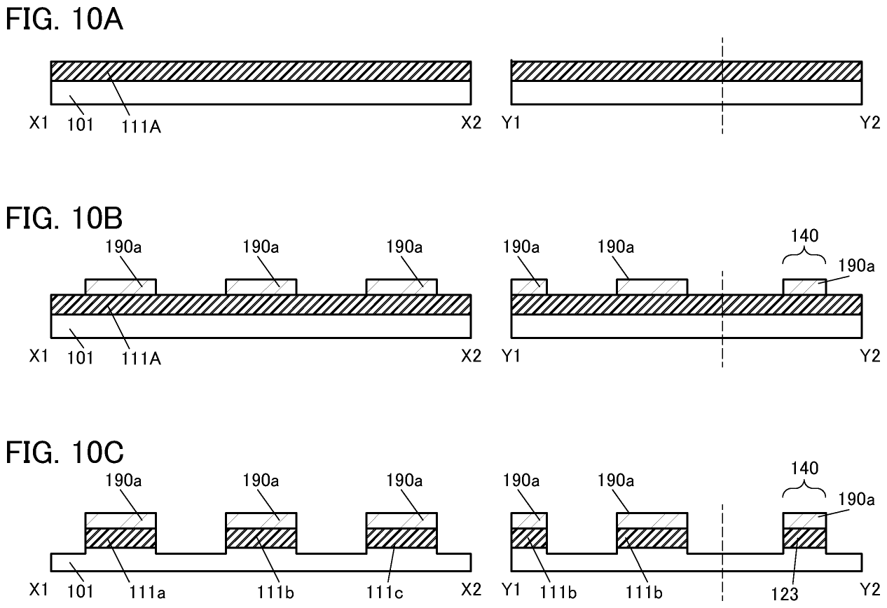

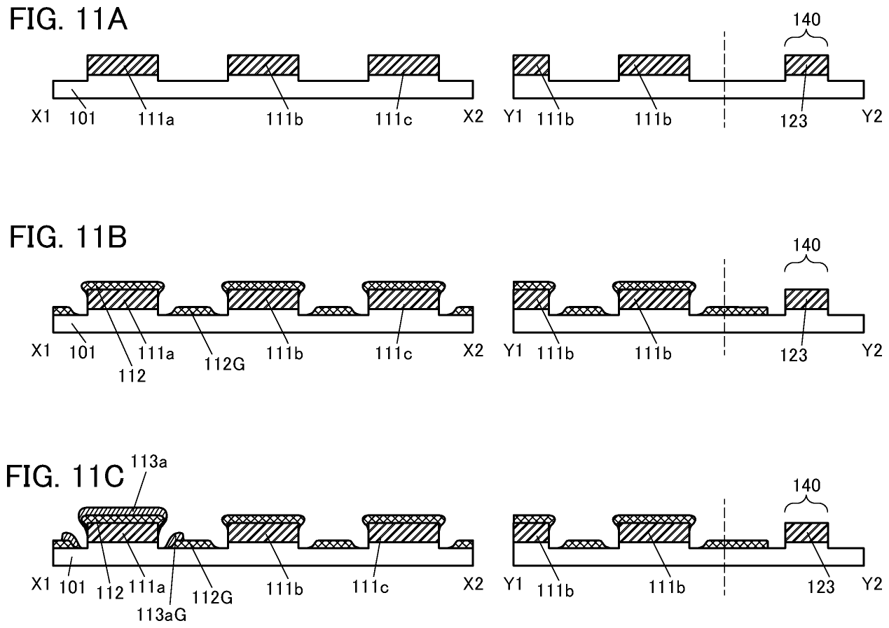

Next, an example of a method for manufacturing a display apparatus is described with reference to FIG. 9A to FIG. 14C. FIG. 9A and FIG. 9B are top views illustrating the method for manufacturing a display apparatus. FIG. 10A to FIG. 10C each illustrate a cross-sectional view along dashed-dotted line X1-X2 and a cross-sectional view along dashed-dotted line Y1-Y2 in FIG. 1A side by side. FIG. 11A to FIG. 14C are similar to FIG. 10.

Thin films that form the display apparatus (insulating films, semiconductor films, conductive films, and the like) can be formed by a sputtering method, a chemical vapor deposition method, a vacuum evaporation method, a pulsed laser deposition (PLD) method, an ALD method, or the like. Examples of a CVD method include a PECVD method and a thermal CVD method. An example of the thermal CVD method is a metal organic chemical vapor deposition (MOCVD: Metal Organic CVD) method.

Alternatively, thin films included in the display apparatus (insulating films, semiconductor films, conductive films, and the like) can be formed by a method such as spin coating, dipping, spray coating, ink-jetting, dispensing, screen printing, or offset printing or with a doctor knife, a slit coater, a roll coater, a curtain coater, or a knife coater.

For manufacture of the light-emitting devices, a vacuum process such as an evaporation method and a solution process such as a spin coating method or an ink-jet method can be especially used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the light-emitting layer, the electron-transport layer, the electron-injection layer, a hole-blocking layer, and an electron-blocking layer) included in the EL layers can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

When the thin films that form the display apparatus are processed, a photolithography method or the like can be used for the processing. Alternatively, thin films may be processed by a nanoimprinting method, a sandblasting method, a lift-off method, or the like. Island-shaped thin films may be directly formed by a deposition method using a blocking mask such as a metal mask.

There are the following two typical methods of a photolithography method. In one of the methods, a resist mask is formed over a thin film that is to be processed, the thin film is processed by etching or the like, and then the resist mask is removed. In the other method, a photosensitive thin film is deposited and then processed into a desired shape by light exposure and development.

For light used for light exposure in a photolithography method, for example, it is possible to use light with the i-line (wavelength: 365 nm), light with the g-line (wavelength: 436 nm), light with the h-line (wavelength: 405 nm), or combined light of any of them. Besides, ultraviolet light, KrF laser light, ArF laser light, or the like can be used. Light exposure may be performed by liquid immersion light exposure technique. As the light used for the light exposure, extreme ultra-violet (EUV) light or X-rays may be used. Furthermore, instead of the light used for the light exposure, an electron beam can also be used. It is preferable to use extreme ultraviolet light, X-rays, or an electron beam because extremely minute processing can be performed. Note that a photomask is not needed when light exposure is performed by scanning with a beam such as an electron beam.

For etching of the thin film, a dry etching method, a wet etching method, a sandblast method, or the like can be used.

First, as illustrated in FIG. 10A, a conductive film 111A is formed over the layer 101 including transistors.

The conductive film 111A is a layer that is processed later to be the pixel electrodes 111a, 111b, and 111c and a conductive layer 123. Accordingly, the conductive film 111A can employ the above-described structure that can be used for the pixel electrode. For formation of the conductive film 111A, a sputtering method or a vacuum evaporation method can be used, for example.

Next, resist masks 190a are formed over the conductive film 111A as illustrated in FIG. 10B. The resist mask can be formed by application of a photosensitive resin (photoresist), light exposure, and development.

The resist mask may be formed using either a positive resist material or a negative resist material.

The resist masks 190a are provided at positions overlapping with a region to be the subpixel 110a later, a region to be the subpixel 110b later, and a region to be the subpixel 110c later, as illustrated in FIG. 9A. One island-shaped pattern is preferably provided for one subpixel 110a, one subpixel 110b, or one subpixel 110c as the resist mask 190a. Alternatively, one band-like pattern for a plurality of the subpixel 110a, the subpixel 110b, and the subpixel 110c aligned in one column (aligned in the Y direction in FIG. 9A) may be formed as the resist mask 190a.

Note that the resist mask 190a is preferably provided also at a position overlapping with a region to be the connection portion 140 later.

Next, as illustrated in FIG. 10C, part of the conductive film 111A is removed using the resist masks 190a, so that the pixel electrodes 111a, 111b, and 111c and the connection portion 140 are formed. Here, the insulating layer included in the layer 101 may be processed using a pattern similar to that of the pixel electrode, and the layer 101 may have a depressed portion between the adjacent pixel electrodes.

The conductive film 111A can be processed by a wet etching method or a dry etching method. The conductive film 111A is preferably processed by anisotropic etching.

After that, the resist masks 190a are removed as illustrated in FIG. 11A. The resist masks 190a can be removed by ashing using oxygen plasma, for example. Alternatively, the resist masks 190a may be removed by a wet process.

Next, the first layers 112 are deposited. A hole-injection layer and a hole-transport layer are formed as the first layers 112. Alternatively, only the hole-injection layer may be formed as the first layers 112. Here, the first layers 112 including the hole-injection layer can be separately deposited into island shapes as illustrated in FIG. 11B when the following condition is satisfied: an angle between the side surface of the pixel electrode 111 and the bottom surface of the pixel electrode 111 is a taper angle θ, the thickness of the pixel electrode 111 is T1, and the thickness of the first layer 112 is T2, the pixel electrode 111 and the first layer 112 are shaped such that T1/T2 is set to greater than or equal to 0.5, preferably greater than or equal to 0.8, further preferably greater than or equal to 1, and still further preferably greater than or equal to 1.5, and θ is greater than or equal to 60° and less than or equal to 140°, preferably greater than or equal to 70° and less than or equal to 140°, and further preferably greater than or equal to 80° and less than or equal to 140°. At this time, the organic layer 112G is formed over the layer 101 between the adjacent pixel electrodes. The first layer 112 can be formed by an evaporation method (including a vacuum evaporation method), a sputtering method, a printing method, an inkjet method, a coating method, or the like. The first layer 112 is preferably formed by an evaporation method. A premix material may be used in the deposition by an evaporation method. Note that in this specification and the like, a premix material is a composite material in which a plurality of materials are combined or mixed in advance.

As illustrated in FIG. 11B, the first layer 112 is positioned inward from the connection portion 140 in the cross-sectional view along Y1-Y2. For example, by using a mask for specifying a deposition area (also referred to as an area mask, a rough metal mask, or the like to be distinguished from a fine metal mask), the first layer 112 can be deposited in different regions. With the combination of the area mask as described above, a light-emitting device can be manufactured in a relatively simple process.

Next, as illustrated in FIG. 11C, the first light-emitting layer 113a including a light-emitting layer emitting red light is formed. The first light-emitting layer 113a can be formed by a method similar to that of the first layer 112, and is preferably formed by an evaporation method. In the manufacturing method of one embodiment of the present invention, the first light-emitting layer 113a is preferably formed into an island shape by a vacuum evaporation method using a metal mask (also referred to as a shadow mask). Here, an organic layer 113aG is formed over the organic layer 112G between the adjacent pixel electrodes.

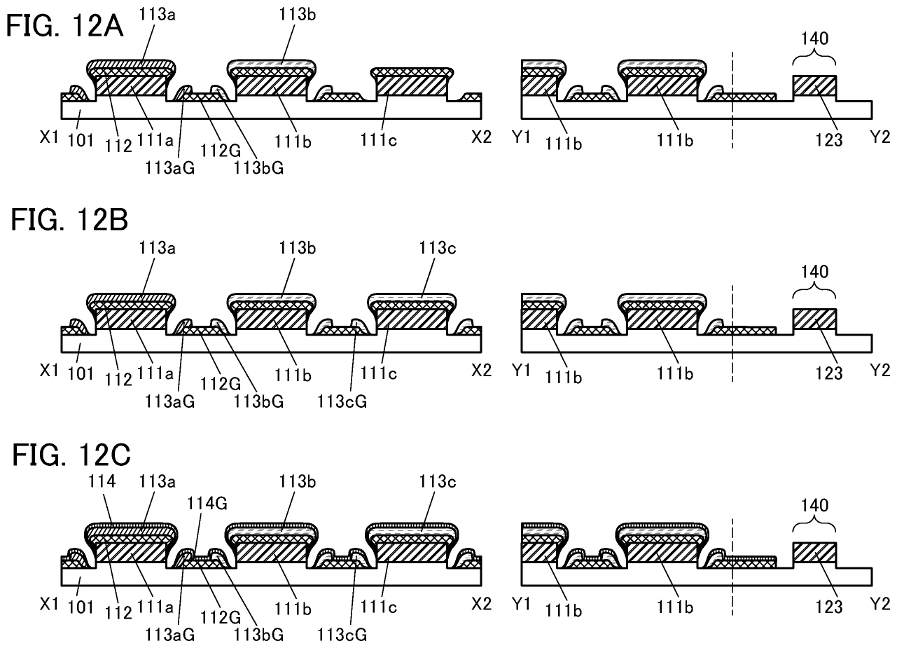

Subsequently, as illustrated in FIG. 12A, the second light-emitting layer 113b including a light-emitting layer emitting green light is formed. The second light-emitting layer 113b can be formed by a method similar to that for the first layer 112, and is preferably formed by an evaporation method. In the manufacturing method of one embodiment of the present invention, the second light-emitting layer 113b is preferably formed into an island shape by a vacuum evaporation method using a metal mask (also referred to as a shadow mask). Here, the organic layer 113bG is formed over the organic layer 112G between the adjacent pixel electrodes.

Next, as illustrated in FIG. 12B, the third light-emitting layer 113c including a light-emitting layer emitting blue light is formed. The third light-emitting layer 113c can be formed by a method similar to that of the first layer 112, and is preferably formed by an evaporation method. In the manufacturing method of one embodiment of the present invention, the third light-emitting layer 113c is preferably formed into an island shape by a vacuum evaporation method using a metal mask (also referred to as a shadow mask). Here, the organic layer 113cG is formed over the organic layer 112G between the adjacent pixel electrodes.

Note that in the formation of the light-emitting layer 113 illustrated in FIG. 11C, FIG. 12A, and FIG. 12B, a hole-transport layer may be formed as part of the light-emitting layer 113 under the light-emitting layer. Furthermore, in the formation of the light-emitting layer 113 illustrated in FIG. 11C, FIG. 12A, and FIG. 12B, an electron-transport layer may be formed as part of the light-emitting layer 113 under the light-emitting layer.

Note that in the above description, the light-emitting layer emitting red light, the light-emitting layer emitting green light, and the light-emitting layer emitting blue light are formed in this order; however, the formation order of red, green, and blue in the method for manufacturing a display apparatus of one embodiment of the present invention is not limited to the above. For example, the formation order of the light-emitting layers may be red, blue, and green: green, red, and blue: green, blue, and red: blue, red, and green: or blue, green, and red.

Next, as shown in FIG. 12C, the second layer 114 is formed. An electron-transport layer can be formed as the second layer 114. The second layer 114 can be formed by a method similar to that for the first layer 112, and is preferably formed by an evaporation method. The second layer 114 is positioned inward from the connection portion 140 in the cross-sectional view along Y1-Y2 like the first layer 112. For example, by using a mask for specifying a deposition area (also referred to as an area mask, a rough metal mask, or the like to be distinguished from a fine metal mask), the second layer 114 can be deposited in different regions. Here, the organic layer 114G is formed over the organic layer 112G between the adjacent pixel electrodes. Note that any one or two of the organic layer 113aG, the organic layer 113bG, and the organic layer 113cG are provided between the organic layer 112G and the organic layer 114G in some cases.

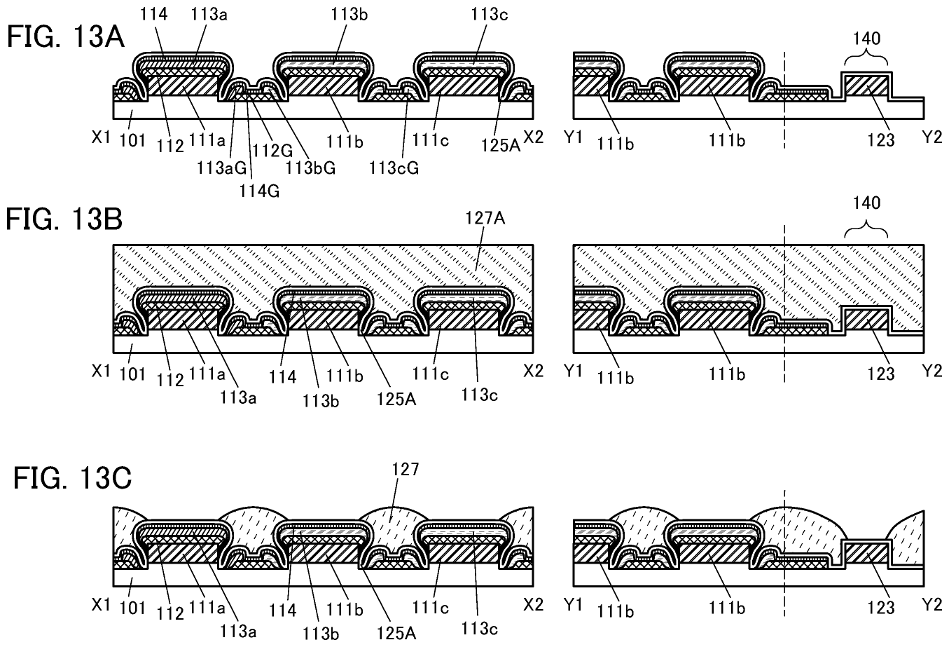

Subsequently, as illustrated in FIG. 13A, an insulating film 125A is formed so as to cover the pixel electrodes 111a, 111b, and 111c, the conductive layer 123, the first layer 112, the first light-emitting layer 113a, the second light-emitting layer 113b, the third light-emitting layer 113c, and the second layer 114.

As the insulating film 125A, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. Alternatively, a metal oxide film such as an indium gallium zinc oxide film may be used.

The insulating film 125A preferably has a function of a barrier insulating film against at least one of water and oxygen. Alternatively, the insulating film 125A preferably has a function of inhibiting diffusion of at least one of water and oxygen. Alternatively, the insulating film 125A preferably has a function of capturing or fixing (also referred to as gettering) at least one of water and oxygen.

Note that in this specification and the like, a barrier insulating film refers to an insulating film having a barrier property. In this specification and the like, a barrier property refers to a function of inhibiting diffusion of a targeted substance (also referred to as having low permeability). Alternatively, a barrier property refers to a function of capturing or fixing (also referred to as gettering) a targeted substance.

When the insulating film 125A has a function of the barrier insulating film or a gettering function, entry of impurities (typically, water or oxygen) that would diffuse into the light-emitting devices from the outside can be inhibited. With such a structure, a highly reliable display apparatus can be provided.

Next, as illustrated in FIG. 13B, an insulating film 127A is formed over the insulating film 125A.

For the insulating film 127A, an organic material can be used. Examples of the organic material include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The insulating film 127A may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. Moreover, the insulating film 127A can be formed using a photosensitive resin. A photoresist may be used as the photosensitive resin. As the photosensitive resin, a positive material or a negative material can be used.

There is no particular limitation on the method of forming the insulating film 127A, and, for example, the insulating film 127A can be formed by a wet deposition method such as spin coating, dipping, spray coating, ink-jetting, dispensing, screen printing, offset printing, doctor blade coating, slit coating, roll coating, curtain coating, or knife coating. Specifically, the insulating film 127A is preferably formed by spin coating.

The insulating film 125A and the insulating film 127A are preferably deposited by a formation method that causes less damage (plasma damage, UV damage, or the like) to the EL layer. In particular, the insulating film 125A, which is formed in contact with the side surface of the EL layer, is preferably deposited by a formation method that causes less damage to the EL layer than the method of forming the insulating film 127A. The insulating film 125A and the insulating film 127A are each formed at a temperature lower than the upper temperature limit of the EL layer (typically at 200° C. or lower, preferably 100° C. or lower, further preferably 80° C. or lower). As the insulating film 125A, an aluminum oxide film can be formed by an ALD method, for example. The use of an ALD method is preferable because the method can reduce damage to the EL layer and enables deposition of a film with good coverage.

Next, as illustrated in FIG. 13C, the insulating film 127A is processed to form the insulating layer 127. The insulating layer 127 is formed so as to be in contact with the side surface of the insulating film 125A and the top surface of the depressed portion.

In the case where the insulating film 127A is processed with use of a photosensitive resin, for example, the photosensitive resin is exposed to light, and then the unnecessary photosensitive resin is removed by development, so that a pattern can be formed. Note that heat treatment may be performed after the development in order to make the top surface of the insulating layer 127 have a gentle projection shape.

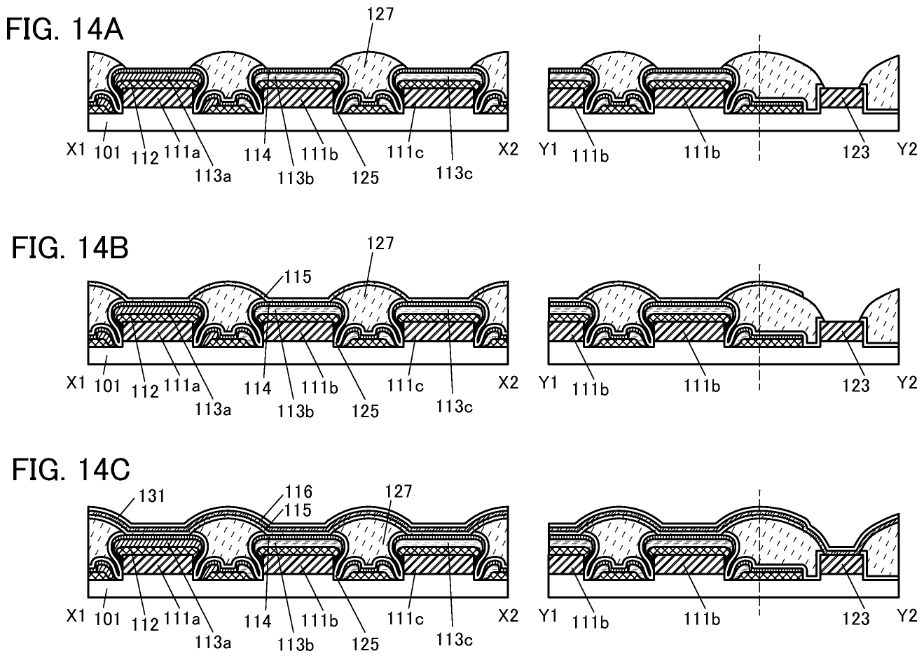

Next, as illustrated in FIG. 14A, part of the insulating film 125A is removed to form the insulating layer 125. With this, the second layer 114 is exposed over the pixel electrodes 111a, 111b, and 111c, and the conductive layer 123 is exposed in the connection portion 140. The insulating layer 125 (furthermore, the insulating layer 127) is provided so as to cover the side surfaces of the pixel electrodes 111a, 111b, and 111c. This can inhibit the pixel electrodes 111a, 111b, and 111c or the like from being in contact with a film to be formed later (a common electrode or a film included in the EL layer), thereby inhibiting a short circuit in the light-emitting device. Moreover, the insulating layer 125 and the insulating layer 127 are preferably provided so as to cover the side surfaces of the first layer 112, the light-emitting layer 113 (the first light-emitting layer 113a, the second light-emitting layer 113b, and the third light-emitting layer 113c), and the second layer 114. This inhibits the side surfaces of these layers from being in contact with a film to be formed later, thereby inhibiting a short circuit in the light-emitting device. It is also possible to suppress damage caused to the first layer 112, the light-emitting layer 113 (the first light-emitting layer 113a, the second light-emitting layer 113b, and the third light-emitting layer 113c), and the second layer 114 in a later step.

In particular, the depressed portion is preferably provided in part of the layer 101 including transistors (specifically, an insulating layer positioned on the outermost surface), in which case the side surfaces of the pixel electrodes 111a, 111b, and 111c can be entirely covered with the insulating layer 125 and the insulating layer 127.

In the connection portion 140, the insulating layer 125 (furthermore, the insulating layer 127) is preferably provided so as to cover the side surface of the conductive layer 123.

The top surface of the insulating layer 125 and the top surface of the insulating layer 127 are each preferably level or substantially level with the top surface of the second layer 114. In addition, the top surface of the insulating layer 127 preferably has a flat shape and may have a projection portion or a depressed portion.

In a step for processing the insulating film 125A, wet etching, dry etching, and the like can be employed. In particular, the use of a wet etching method can reduce damage to the second layer 114 at the time of removing the insulating layer 125, as compared to the case of using a dry etching method.

In addition, the step for processing the insulating film 125A may be combined with the step for processing the insulating film 127A. When processing is performed with appropriate combination of the step for processing the insulating film 125A and the step for processing the insulating film 127A, the structures of the insulating layer 125 and the insulating layer 127 can be any of a variety of structures as illustrated in FIG. 2 to FIG. 4.

One or both of the insulating film 125A and the insulating film 127A may be removed by being dissolved in a solvent such as water or alcohol. Examples of alcohol include ethyl alcohol, methyl alcohol, isopropyl alcohol (IPA), and glycerin.

After the insulating layer 125 and the insulating layer 127 is formed, drying treatment may be performed to remove water included in the EL layer and water adsorbed onto the surface of the EL layer. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., and further preferably higher than or equal to 70° C. and lower than or equal to 120° C. Employing a reduced-pressure atmosphere is preferable, in which case drying at a lower temperature is possible.

Next, as illustrated in FIG. 14B, the third layer 115 is formed so as to cover the insulating layer 125, the insulating layer 127, and the second layer 114. An electron-injection layer can be formed as the third layer 115.

Materials that can be used for the third layer 115 are as described above. The third layer 115 can be formed by an evaporation method (including a vacuum evaporation method), a transfer method, a printing method, an inkjet method, a coating method, or the like. The third layer 115 may be formed using a premix material.

Here, in the case where the insulating layer 125 and the insulating layer 127 are not provided, the pixel electrode 111 or the like might be in contact with the third layer 115. A contact between these layers might cause a short circuit of the light-emitting devices when the third layer 115 has high conductivity, for example. Meanwhile, in the display apparatus of one embodiment of the present invention, the insulating layers 125 and 127 cover the first layer 112, the light-emitting layer 113, the second layer 114, and the pixel electrodes 111a, 111b, and 111c; hence, the third layer 115 with high conductivity can be prevented from being in contact with these layers, so that a short circuit of the light-emitting devices can be suppressed. As a result, the reliability of the light-emitting devices can be increased.

Then, as illustrated in FIG. 14C, the common electrode 116 is formed over the third layer 115 and over the conductive layer 123. As illustrated in FIG. 14C, the conductive layer 123 and the common electrode 116 are electrically connected to each other. Note that although FIG. 14B illustrates an example in which a mask for specifying a deposition area (also referred to as an area mask, a rough metal mask, or the like to be distinguished from a fine metal mask) is used at the time of deposition of the third layer 115 as in the deposition of the first layer 112, the third layer 115 may be formed over the entire surface, and the conductive layer 123 and the common electrode 116 may be electrically connected to each other through the third layer 115.

Materials that can be used for the common electrode 116 are as described above. The common electrode 116 can be formed by a sputtering method or a vacuum evaporation method, for example. Alternatively, a film formed by an evaporation method and a film formed by a sputtering method may be stacked.

After that, the protective layer 131 is formed over the common electrode 116 as illustrated in FIG. 14C.

Materials and deposition methods that can be used for the protective layer 131 are as described above. Examples of methods for depositing the protective layer 131 include a vacuum evaporation method, a sputtering method, a CVD method, and an ALD method. The protective layer 131 may have a single-layer structure or a stacked-layer structure. When the protective layer 131 has a stacked-layer structure, films formed by different deposition methods may be stacked.

Note that although an example is described in which a mask for specifying a deposition area (also referred to as an area mask, a rough metal mask, or the like) is used at the time of the deposition of the third layer 115 and the common electrode 116, the mask for specifying a deposition area is not necessarily used. For example, in the case where the mask is not used for the deposition of the common electrode 116, after the step illustrated in FIG. 13B, a resist mask 190b may be formed over the common electrode 116 as illustrated in FIG. 9B to process the common electrode 116, and then the step of forming the protective layer 131 may be performed.

The display apparatus of one embodiment of the present invention includes an insulating layer that covers the side surfaces of a pixel electrode, a light-emitting layer, and a carrier-transport layer. In the manufacturing process of the display apparatus, the carrier-transport layer can be separately formed in a self-aligned manner, whereby crosstalk is reduced in the display apparatus. In addition, the insulating layer inhibits the pixel electrode from being in contact with a carrier-injection layer or a common electrode, thereby inhibiting a short circuit in the light-emitting device.

This embodiment can be combined with the other embodiments as appropriate. In this specification, in the case where a plurality of structure examples are described in one embodiment, the structure examples can be combined as appropriate.

### Embodiment 2

In this embodiment, a light-emitting device that can be used in a display panel of one embodiment of the present invention is described.

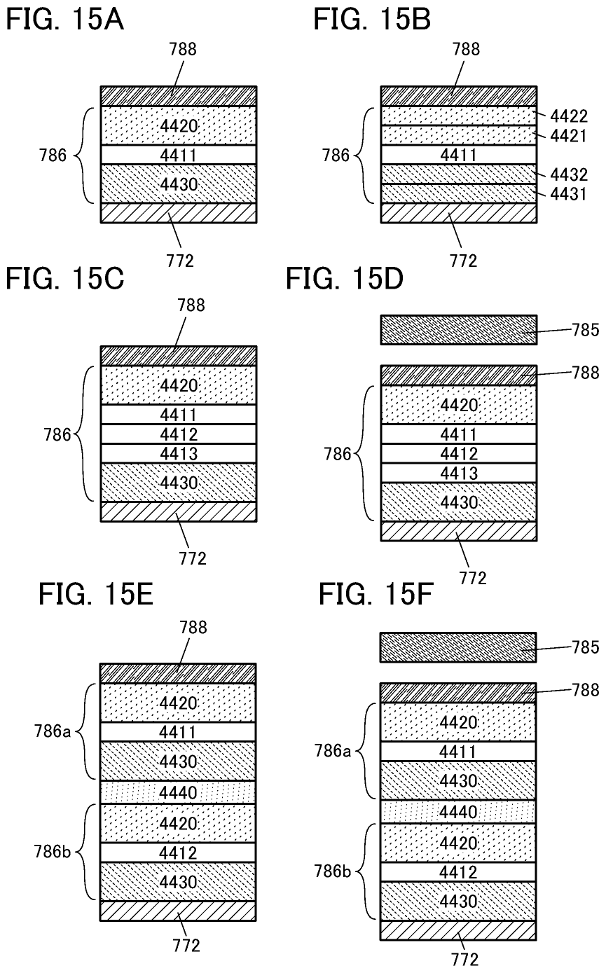

As illustrated in FIG. 15A, the light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430 provided between the pair of electrodes can function as a single light-emitting unit, and the structure in FIG. 15A is referred to as a single structure in this specification.

FIG. 15B is a modification example of the EL layer 786 included in the light-emitting device illustrated in FIG. 15A. Specifically, the light-emitting device illustrated in FIG. 15B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. When the lower electrode 772 is an anode and the upper electrode 788 is a cathode, for example, the layer 4431 functions as a hole-injection layer, the layer 4432 functions as a hole-transport layer, the layer 4421 functions as an electron-transport layer, and the layer 4422 functions as an electron-injection layer. Alternatively, when the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layered structure, carriers can be efficiently injected to the light-emitting layer 4411, and the efficiency of the recombination of carriers in the light-emitting layer 4411 can be enhanced.

Note that a structure in which a plurality of light-emitting layers (light-emitting layers 4411, 4412, and 4413) are provided between the layer 4420 and the layer 4430 as illustrated in FIG. 15C or FIG. 15D is a variation of the single structure.

A structure in which a plurality of light-emitting units (an EL layer 786a and an EL layer 786b) are connected in series with a charge-generation layer 4440 therebetween as illustrated in FIG. 15E or FIG. 15F is referred to as a tandem structure in this specification. Note that a tandem structure may be referred to as a stack structure. The tandem structure enables a light-emitting device capable of high luminance light emission.

In FIG. 15C and FIG. 15D, light-emitting materials that emit light of the same color, or moreover, the same light-emitting material may be used for the light-emitting layer 4411, the light-emitting layer 4412, and the light-emitting layer 4413. For example, a light-emitting material that emits blue light may be used for the light-emitting layer 4411, the light-emitting layer 4412, and the light-emitting layer 4413. A color conversion layer may be provided as a layer 785 illustrated in FIG. 15D.

Alternatively, light-emitting materials that emit light of different colors may be used for the light-emitting layer 4411, the light-emitting layer 4412, and the light-emitting layer 4413. White light emission can be obtained when light emitted from the light-emitting layer 4411, light emitted from the light-emitting layer 4412, and light emitted from the light-emitting layer 4413 have a relationship of complementary colors. A color filter (also referred to as a coloring layer) may be provided as the layer 785 illustrated in FIG. 15D. When white light passes through a color filter, light of a desired color can be obtained.

In FIG. 15E and FIG. 15F, light-emitting materials that emit light of the same color, or moreover, the same light-emitting material may be used for the light-emitting layer 4411 and the light-emitting layer 4412. Alternatively, light-emitting materials that emit light of different colors may be used for the light-emitting layer 4411 and the light-emitting layer 4412. White light emission can be obtained when light emitted from the light-emitting layer 4411 and light emitted from the light-emitting layer 4412 have a relationship of complementary colors. FIG. 15F illustrates an example in which the layer 785 is further provided. One or both of a color conversion layer and a color filter (coloring layer) can be used as the layer 785.

Also in the structures illustrated in FIG. 15C, FIG. 15D, FIG. 15E, and FIG. 15F, the layer 4420 and the layer 4430 may each have a stacked-layer structure of two or more layers as illustrated in FIG. 15B.

A structure in which light-emitting devices of different emission colors (e.g., blue (B), green (G), and red (R)) are separately formed is referred to as an SBS(Side By Side) structure in some cases.

The emission color of the light-emitting device can be red, green, blue, cyan, magenta, yellow, white, or the like depending on the material of the EL layer 786. Furthermore, the color purity can be further increased when the light-emitting device has a microcavity structure.

A light-emitting device that emits white light preferably contains two or more kinds of light-emitting substances in its light-emitting layer. To obtain white light emission, two or more light-emitting substances are selected such that their emission colors are complementary. For example, when the emission color of a first light-emitting layer and the emission color of a second light-emitting layer are complementary colors, it is possible to obtain a light-emitting device which emits white light as a whole. The same can be applied to a light-emitting device including three or more light-emitting layers.

The light-emitting layer preferably contains two or more light-emitting substances that emit light of R (red), G (green), B (blue), Y (yellow), O (orange), and the like. Alternatively, it is preferable that the light-emitting layer contain two or more light-emitting substances each of which emits light containing two or more spectral components of colors of R, G, and B.

This embodiment can be combined with the other embodiments as appropriate.

### Embodiment 3

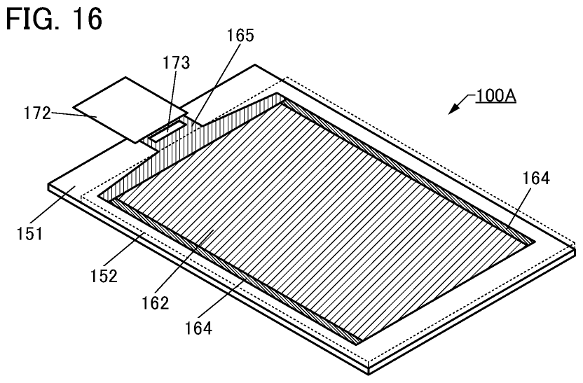

In this embodiment, a display apparatus of one embodiment of the present invention is described with reference to FIG. 16 to FIG. 21.

The display apparatus of this embodiment can be a high-definition display apparatus or a large-sized display apparatus. Accordingly, the display apparatus of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Apparatus 100A]

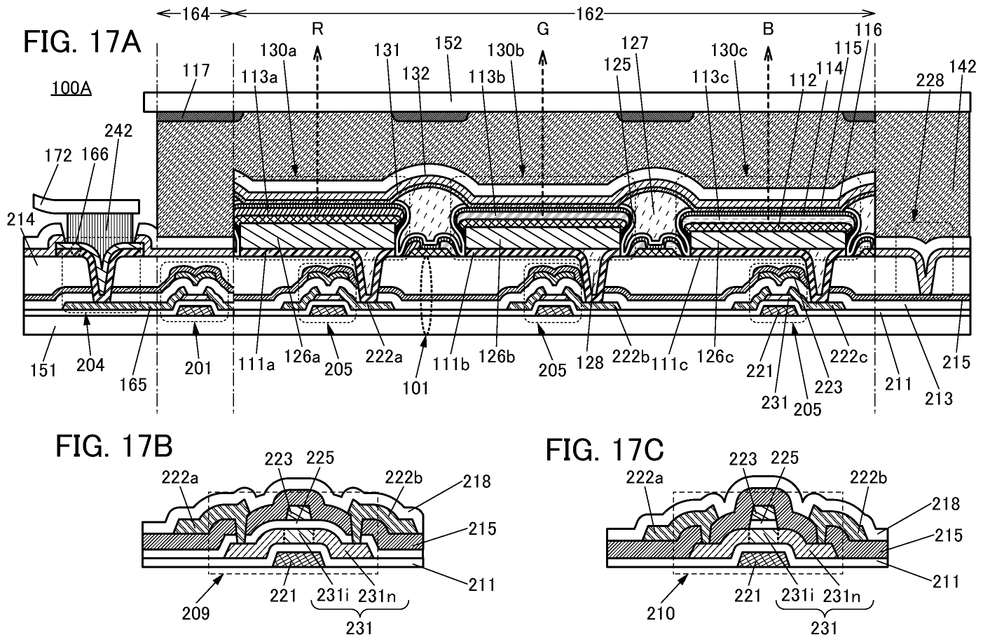

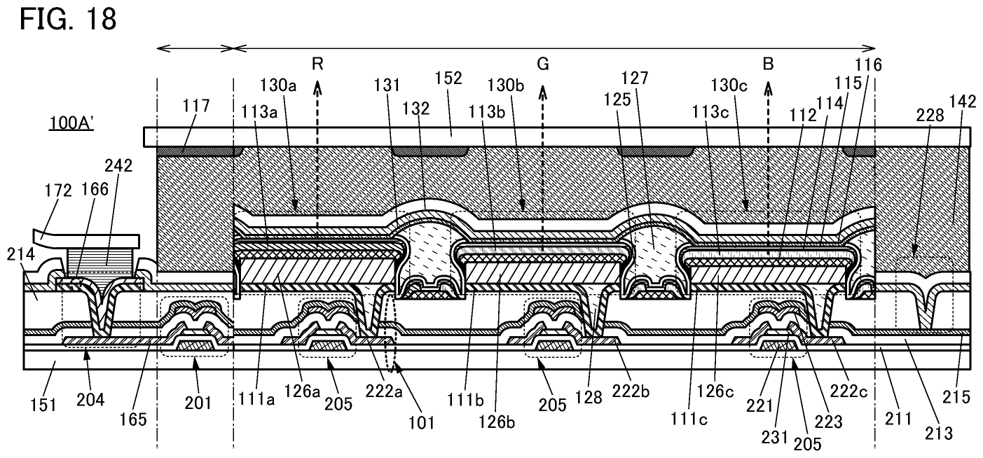

FIG. 16 is a perspective view of a display apparatus 100A, and FIG. 17A is a cross-sectional view of the display apparatus 100A. FIG. 18, which is a modification example of FIG. 17A, illustrates a display apparatus 100A′.

The display apparatus 100A has a structure in which a substrate 152 and a substrate 151 are bonded to each other. In FIG. 16, the substrate 152 is denoted by dashed line.

The display apparatus 100A includes a display portion 162, a circuit 164, a wiring 165, and the like. FIG. 16 illustrates an example in which an IC 173 and an FPC 172 are mounted on the display apparatus 100A. Thus, the structure illustrated in FIG. 16 can be regarded as a display module including the display apparatus 100A, the IC (integrated circuit), and the FPC.

As the circuit 164, a scan line driver circuit can be used, for example.

The wiring 165 has a function of supplying a signal and electric power to the display portion 162 and the circuit 164. The signal and electric power are input to the wiring 165 from the outside through the FPC 172 or from the IC 173.

FIG. 16 illustrates an example in which the IC 173 is provided over the substrate 151 by a COG (Chip On Glass) method, a COF (Chip on Film) method, or the like. An IC including a scan line driver circuit, a signal line driver circuit, or the like can be used as the IC 173, for example. Note that the display apparatus 100A and the display module are not necessarily provided with an IC. The IC may be mounted on the FPC by a COF method or the like.

FIG. 17A illustrates an example of cross sections of part of a region including the FPC 172, part of the circuit 164, part of the display portion 162, and part of a region including an end portion of the display apparatus 100A.

The display apparatus 100A illustrated in FIG. 17A includes a transistor 201, a transistor 205, the light-emitting devices 130a, 130b, and 130c, and the like between the substrate 151 and the substrate 152. The light-emitting devices 130a. 130b, and 130c have a function of emitting light of different colors.

In the case where a pixel of the display apparatus includes three subpixels including the light-emitting devices 130a, 130b, and 130c emitting light of different colors, the three subpixels can be subpixels of three colors of R, G, and B or subpixels of three colors of yellow (Y), cyan (C), and magenta (M), for example. In the case where four subpixels are included, the four subpixels can be subpixels of four colors of R, G, B, and white (W) or subpixels of four colors of R, G, B, and Y, for example.

The stacked-layer structures of the light-emitting devices 130a, 130b, and 130c are the same as those illustrated in FIG. 1B except that the light-emitting devices have optical adjustment layers 126 (a conductive layer 126a, a conductive layer 126b, and a conductive layer 126c) between the pixel electrodes and the EL layers. The light-emitting device 130a includes a conductive layer 126a, the light-emitting device 130b includes a conductive layer 126b, and the light-emitting device 130c includes a conductive layer 126c. Embodiment 1 can be referred to for the details of the light-emitting devices. The side surfaces of the pixel electrodes 111a, 111b, and 111c, the conductive layers 126a, 126b, and 126c, the first layer 112, the light-emitting layer 113, and the second layer 114 are covered with the insulating layers 125 and 127. The third layer 115 is provided over the first layer 112, the light-emitting layer 113, the second layer 114, and the insulating layers 125 and 127. The common electrode 116 is provided over the third layer 115. The protective layer 131 is provided over the light-emitting devices 130a, 130b, and 130c. The protective layer 132 is provided over the protective layer 131. For the structure between the pixel electrodes, the structure between the end portions of the pixel electrodes, and the like, those illustrated in FIG. 1 to FIG. 7 can be referred to. For example, the pixel electrode 111a in FIG. 1 to FIG. 7 corresponds to the pixel electrode 111a and the conductive layer 126a in FIG. 17A and FIG. 18, and the height of the step between the adjacent pixel electrodes in FIG. 17A corresponds to the heights of the pixel electrode 111a and the conductive layer 126a. Furthermore, the height of the step between the adjacent pixel electrodes in FIG. 18 can be the sum of the heights of the pixel electrode 111a and the conductive layer 126a and the depth of the depressed portion (the step portion) provided in the insulating layer 214 at the portion. Note that in FIG. 18, portions other than the depressed portion provided in the insulating layer 214 have the same structure as that in FIG. 17.

In addition, as illustrated in FIG. 17A, the optical adjustment layers 126 provided in the light-emitting devices 130 preferably have different thicknesses. Alternatively, in the case where the optical adjustment layers 126 in the light-emitting devices have the same thickness, the EL layers in the light-emitting devices preferably have different thicknesses.

The protective layer 132 and the substrate 152 are bonded to each other with an adhesive layer 142. A solid sealing structure, a hollow sealing structure, or the like can be employed to seal the light-emitting devices. In FIG. 17A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. Here, the adhesive layer 142 may be provided so as not to overlap with the light-emitting device. The space may be filled with a resin different from that of the frame-like adhesive layer 142.

The pixel electrodes 111a, 111b, and 111c are each connected to a conductive layer 222a, a conductive layer 222b, and a conductive layer 222c included in the transistor 205 through an opening provided in the insulating layer 214.

Depressed portions are formed in the pixel electrodes 111a, 111b, and 111c to cover the openings provided in the insulating layer 214. A layer 128 is preferably embedded in the depressed portion. It is preferable that the conductive layer 126a be formed over the pixel electrode 111a and the layer 128, the conductive layer 126b be formed over the pixel electrode 111b and the layer 128, and the conductive layer 126c be formed over the pixel electrode 111c and the layer 128. The conductive layers 126a, 126b, and 126c can also be referred to as pixel electrodes.

The layer 128 has a function of filling the depressed portions of the pixel electrodes 111a. 111b, and 111c. By providing the layer 128, unevenness of a surface where the EL layer is formed can be reduced, and coverage can be improved. By providing the conductive layers 126a, 126b, and 126c electrically connected to the pixel electrodes 111a, 111b, and 111c, respectively, over the pixel electrodes 111a, 111b, and 111c and the layer 128, regions overlapping with the depressed portions of the pixel electrodes 111a, 111b, and 111c can be used as light-emitting regions in some cases. Thus, the aperture ratio of a pixel can be increased.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used as the layer 128. For the layer 128, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 128. As the photosensitive resin, a positive material or a negative material can be used.

When a photosensitive resin is used, the layer 128 can be formed through only light-exposure and development steps, reducing the influence of dry etching, wet etching, or the like on the surfaces of the pixel electrodes 111a, 111b, and 111c. When the layer 128 is formed using a negative photosensitive resin, the layer 128 can sometimes be formed using the same photomask (light-exposure mask) as the photomask used for forming the opening in the insulating layer 214.

The conductive layer 126a is provided over the pixel electrode 111a and the layer 128. The conductive layer 126a includes a first region in contact with the top surface of the pixel electrode 111a and a second region in contact with the top surface of the layer 128. The top surface of the pixel electrode 111a in contact with the first region and the top surface of the layer 128 in contact with the second region are preferably level or substantially level with each other.

Similarly, the conductive layer 126b is provided over the pixel electrode 111b and over the layer 128. The conductive layer 126b includes a first region in contact with the top surface of the pixel electrode 111b and a second region in contact with the top surface of the layer 128. The top surface of the pixel electrode 111b in contact with the first region and the top surface of the layer 128 in contact with the second region are preferably level or substantially level with each other.

The conductive layer 126c is provided over the pixel electrode 111c and over the layer 128. The conductive layer 126c includes a first region in contact with the top surface of the pixel electrode 111c and a second region in contact with the top surface of the layer 128. The top surface of the pixel electrode 111c in contact with the first region and the top surface of the layer 128 in contact with the second region are preferably level or substantially level with each other.

The pixel electrode contains a material that reflects visible light, and the counter electrode contains a material that transmits visible light.

The display apparatus 100A has a top emission structure. Light from the light-emitting device is emitted toward the substrate 152. For the substrate 152, a material having a high transmitting property with respect to visible light is preferably used.

A stacked-layer structure including the substrate 151 and the components thereover up to the insulating layer 214 corresponds to the layer 101 including transistors in Embodiment 1.

The transistor 201 and the transistor 205 are formed over the substrate 151. These transistors can be fabricated using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This is because such an insulating layer can function as a barrier layer. Such a structure can effectively inhibit diffusion of impurities into the transistors from the outside and increase the reliability of a display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

Here, an organic insulating film often has a lower barrier property than an inorganic insulating film. Accordingly, the organic insulating film preferably has an opening in the vicinity of the end portion of the display apparatus 100A. This can inhibit entry of impurities from the end portion of the display apparatus 100A through the organic insulating film. Alternatively, the organic insulating film may be formed so that its end portion is positioned inward from the end portion of the display apparatus 100A, to prevent the organic insulating film from being exposed at the end portion of the display apparatus 100A.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 214 may have a stacked-layer structure including an organic insulating film and an inorganic insulating film. The outermost layer of the insulating layer 214 preferably has a function of an etching protective film. Accordingly, a depressed portion can be inhibited from being formed in the insulating layer 214 at the time of processing the pixel electrode 111a, the conductive layer 126a, or the like. Alternatively, a depressed portion may be provided in the insulating layer 214 at the time of processing the pixel electrode 111a, the conductive layer 126a, or the like.

In a region 228 illustrated in FIG. 17A, an opening is formed in the insulating layer 214. This can inhibit entry of impurities into the display portion 162 from the outside through the insulating layer 214 even when an organic insulating film is used as the insulating layer 214. Consequently, the reliability of the display apparatus 100A can be increased.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, or an inverted staggered transistor can be used. Either of a top-gate transistor structure and a bottom-gate transistor structure can be used. Alternatively, gates may be provided above and below a semiconductor layer in which a channel is formed.

The structure in which the semiconductor layer in which a channel is formed is provided between two gates is used for the transistor 201 and the transistor 205. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and any of an amorphous semiconductor and a semiconductor having crystallinity (a microcrystalline semiconductor, a polycrystalline semiconductor, a single crystal semiconductor, or a semiconductor partly including crystal regions) may be used. It is preferable to use a semiconductor having crystallinity, in which case deterioration of the transistor characteristics can be inhibited.

It is preferable that a semiconductor layer of a transistor contain a metal oxide (also referred to as an oxide semiconductor). That is, a transistor including a metal oxide in its channel formation region (hereinafter also referred to as an OS transistor) is preferably used for the display apparatus of this embodiment. Alternatively, a semiconductor layer of a transistor may contain silicon. Examples of silicon include amorphous silicon and crystalline silicon (e.g., low-temperature polysilicon or single crystal silicon).

The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin.

It is particularly preferable that an oxide containing indium (In), gallium (Ga), and zinc (Zn) (also referred to as IGZO) be used for the semiconductor layer.

When the semiconductor layer is In-M-Zn oxide, the atomic ratio of In is preferably greater than or equal to the atomic ratio of M in the In-M-Zn oxide. Examples of the atomic ratio of the metal elements in such In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. When the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

The transistor included in the circuit 164 and the transistor included in the display portion 162 may have the same structure or different structures. One structure or two or more kinds of structures may be employed for a plurality of transistors included in the circuit 164. Similarly, one structure or two or more kinds of structures may be employed for a plurality of transistors included in the display portion 162.

FIG. 17B and FIG. 17C illustrate other structure examples of transistors.

The transistor 209 and the transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the low-resistance regions 231n, the conductive layer 222b connected to the other low-resistance region 231n, the insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 17B illustrates an example of the transistor 209 in which the insulating layer 225 covers the top and side surfaces of the semiconductor layer 231. The conductive layer 222a and the conductive layer 222b are connected to the corresponding low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 17C, the insulating layer 225 overlaps with the channel formation region 231i of the semiconductor layer 231 and does not overlap with the low-resistance regions 231n. The structure illustrated in FIG. 17C is obtained by processing the insulating layer 225 with the conductive layer 223 as a mask, for example. In FIG. 17C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. An example is illustrated in which the conductive layer 166 has a stacked-layer structure of a conductive film obtained by processing the same conductive film as the pixel electrodes 111a, 111b, and 111c and a conductive film obtained by processing the same conductive film as the conductive layers 126a, 126b, and 126c. On the top surface of the connection portion 204, the conductive layer 166 is exposed. Thus, the connection portion 204 and the FPC 172 can be electrically connected to each other through the connection layer 242.

As illustrated in FIG. 17A, a light-blocking layer 117 is preferably provided on the surface of the substrate 152 on the substrate 151 side.

A variety of optical members can be arranged on the outer surface of the substrate 152. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 152.

The protective layer 131 and the protective layer 132 provided to cover the light-emitting device inhibit an impurity such as water from entering the light-emitting device. As a result, the reliability of the light-emitting device can be enhanced.

In the region 228 in the vicinity of the end portion of the display apparatus 100A, the insulating layer 215 and the protective layer 131 or the protective layer 132 are preferably in contact with each other through an opening in the insulating layer 214. In particular, the inorganic insulating films are preferably in contact with each other. This can inhibit entry of impurities into the display portion 162 from the outside through the organic insulating film. Consequently, the reliability of the display apparatus 100A can be enhanced.

For each of the substrate 151 and the substrate 152, glass, quartz, ceramics, sapphire, a resin, a metal, an alloy, a semiconductor, or the like can be used. For the substrate on the side from which light from the light-emitting device is extracted, a material that transmits the light is used. When a flexible material is used for each of the substrate 151 and the substrate 152, the flexibility of the display apparatus can be increased. Furthermore, a polarizing plate may be used as the substrate 151 or the substrate 152.

For each of the substrate 151 and the substrate 152, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for one or both of the substrate 151 and the substrate 152.

In the case where a circularly polarizing plate overlaps with the display apparatus, a highly optically isotropic substrate is preferably used as the substrate included in the display 0 apparatus. A highly optically isotropic substrate has a low birefringence (that can also be referred to as a small amount of birefringence).

The absolute value of a retardation (phase difference) of a highly optically isotropic substrate is preferably less than or equal to 30 nm, further preferably less than or equal to 20 nm, and still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display panel might be changed, e.g., creases are generated. Thus, for the substrate, a film with a low water absorption rate is preferably used. For example, the water absorption rate of the film is preferably 1% or lower, further preferably 0.1% or lower, and still further preferably 0.01% or lower.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

As the connection layer 242, an anisotropic conductive film (ACF), an anisotropic conductive paste (ACP), or the like can be used.

As materials for the gates, the source, and the drain of a transistor and conductive layers such as a variety of wirings and electrodes included in the display apparatus, any of metals such as aluminum, titanium, chromium, nickel, copper, yttrium, zirconium, molybdenum, silver, tantalum, and tungsten, or an alloy containing any of these metals as its main component can be used, for example. A single-layer structure or a stacked-layer structure including a film containing any of these materials can be used.

As a light-transmitting conductive material, a conductive oxide such as indium oxide, indium tin oxide, indium zinc oxide, zinc oxide, or zinc oxide containing gallium, or graphene can be used. It is also possible to use a metal material such as gold, silver, platinum, magnesium, nickel, tungsten, chromium, molybdenum, iron, cobalt, copper, palladium, or titanium: or an alloy material containing any of these metal materials. Alternatively, a nitride of the metal material (e.g., titanium nitride) or the like may be used. Note that in the case of using the metal material or the alloy material (or the nitride thereof), the thickness is preferably set small enough to transmit light. Alternatively, a stacked film of any of the above materials can be used for the conductive layers. For example, a stacked film of indium tin oxide and an alloy of silver and magnesium is preferably used because conductivity can be increased. They can also be used for conductive layers such as wirings and electrodes included in the display apparatus, and conductive layers (e.g., a conductive layer functioning as a pixel electrode or a common electrode) included in a light-emitting device.

Examples of insulating materials that can be used for the insulating layers include a resin such as an acrylic resin or an epoxy resin, and an inorganic insulating material such as silicon oxide, silicon oxynitride, silicon nitride oxide, silicon nitride, or aluminum oxide.

### [Display Apparatus 100B]

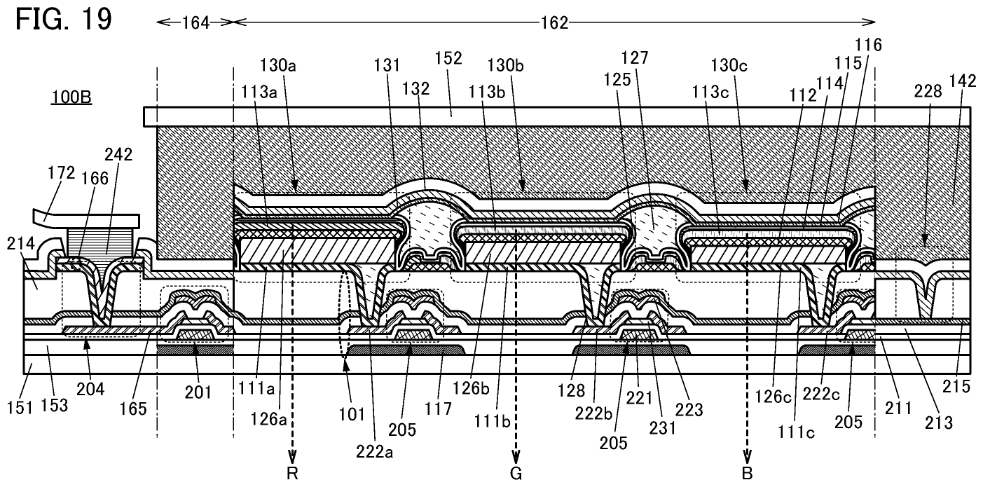

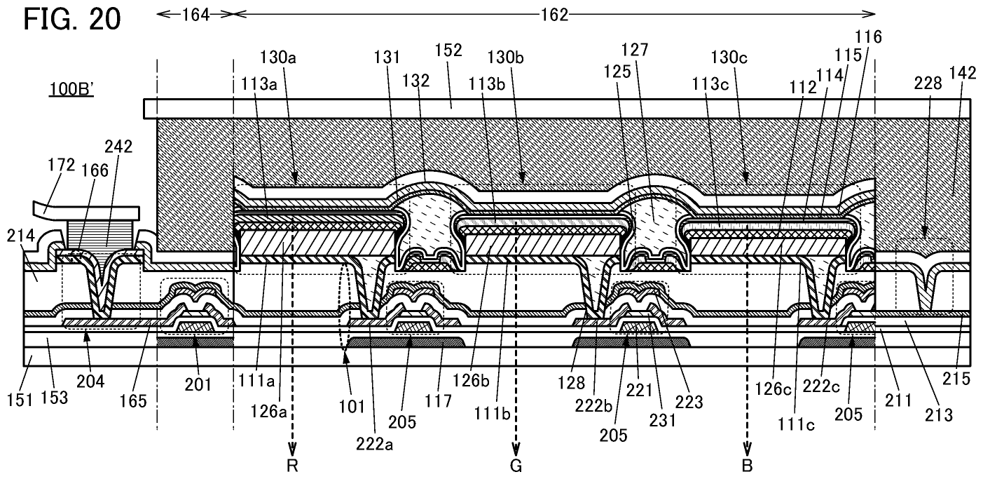

A display apparatus 100B illustrated in FIG. 19 and a display apparatus 100B′ illustrated in FIG. 20 are different from the display apparatus 100A mainly in having a bottom-emission structure. Note that portions similar to those of the display apparatus 100A are not described. Note that the display apparatus 100B′ illustrated in FIG. 20 has the same structure as the display apparatus 100B illustrated in FIG. 19 except that the insulating layer 214 includes a depressed portion (a step portion) between the pixel electrodes. Note that although FIG. 19 and FIG. 20 illustrates a subpixel including the first layer 112 and a subpixel including the light-emitting layer 113, three or more kinds of subpixels can be provided as in FIG. 17, for example.

Light from the light-emitting device is emitted toward the substrate 151. For the substrate 151, a material having a high transmitting property with respect to visible light is preferably used. By contrast, there is no limitation on the light-transmitting property of a material used for the substrate 152.

In the display apparatus 100B, the pixel electrodes 111a, 111b, and 111c and the conductive layers 126a, 126b, and 126c contain a material that transmits visible light, and the common electrode 116 contains a material that reflects visible light. Here, the conductive layer 166 that is obtained by processing the same conductive film as the pixel electrodes 111a, 111b, and 111c and the conductive layers 126a, 126b, and 126c also contains a material that transmits visible light.

The light-blocking layer 117 is preferably formed between the substrate 151 and the transistor 201 and between the substrate 151 and the transistor 205. FIG. 19 illustrates an example in which the light-blocking layer 117 is provided over the substrate 151, an insulating layer 153 is provided over the light-blocking layer 117, and the transistors 201 and 205 and the like are provided over the insulating layer 153.

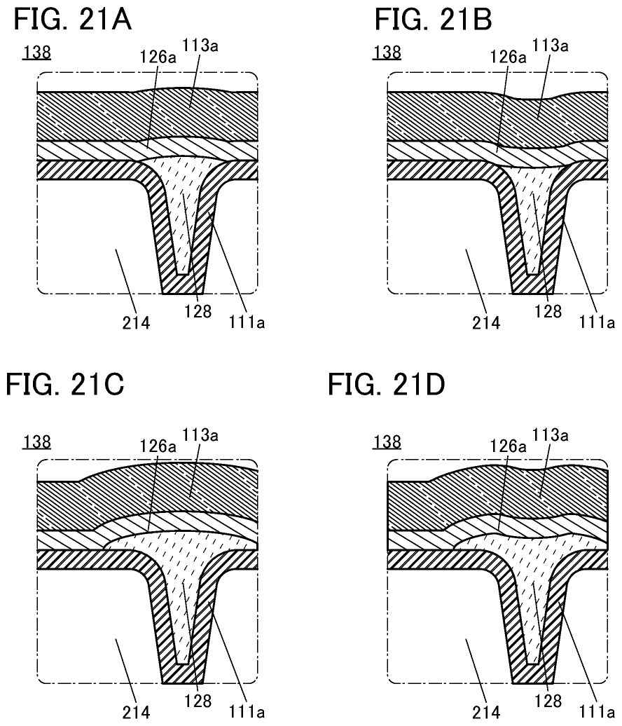

Here, FIG. 21A to FIG. 21D illustrate cross-sectional structures of a region 138 including the pixel electrode 111a, the layer 128, and the vicinity thereof in the display apparatus 100A and the display apparatus 100B. Note that the description of FIG. 21A to FIG. 21D is also applicable to the light-emitting device 130b and the light-emitting device 130c.

FIG. 17A, FIG. 18, FIG. 19, and FIG. 20 each illustrate an example in which the top surface of the layer 128 and the top surface of the pixel electrode 111a are substantially level with each other: however, the present invention is not limited thereto. For example, as illustrated in FIG. 21A, the top surface level of the layer 128 may be higher than that of the pixel electrode 111a. In this case, the top surface of the layer 128 has a convex shape that is gently bulged toward the center.

As illustrated in FIG. 21B, the top surface level of the layer 128 may be lower than that of the pixel electrode 111a. In this case, the top surface of the layer 128 has a concave shape that is gently recessed toward the center.

When the top surface level of the layer 128 is higher than that of the pixel electrode 111a as illustrated in FIG. 21C, the upper portion of the layer 128 may be formed to extend beyond a depressed portion formed in the pixel electrode 111a. In this case, part of the layer 128 may be formed to cover part of the pixel electrode 111a which is substantially flat.

As illustrated in FIG. 21D, part of the top surface of layer 128 has another depressed portion in the structure illustrated in FIG. 21C, in some cases. The depressed portion has a shape that is gently recessed toward the center.

This embodiment can be combined with the other embodiments as appropriate.

### Embodiment 4

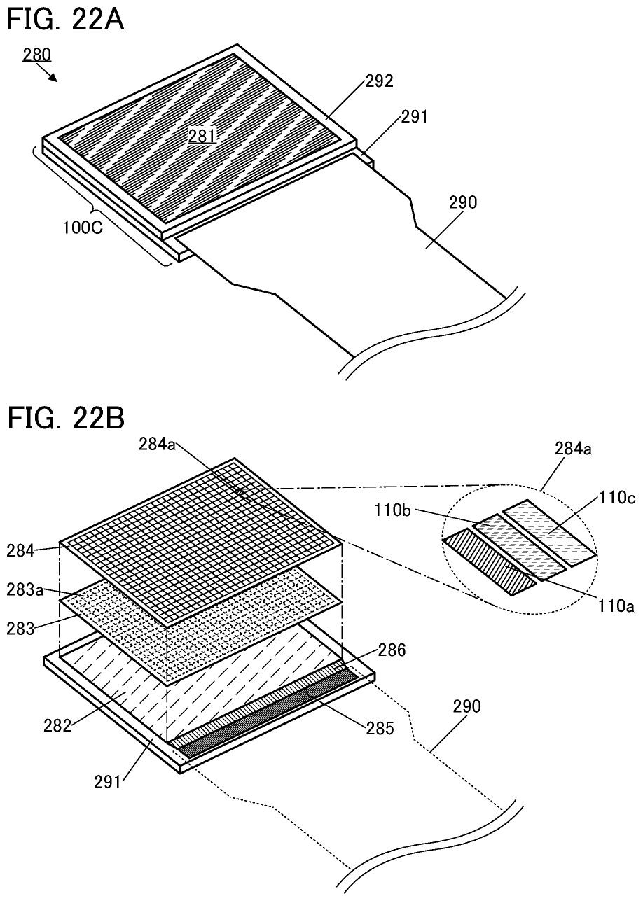

In this embodiment, display apparatuses of one embodiment of the present invention are described with reference to FIG. 22 to FIG. 25.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices capable of being worn on a head, such as a VR (Virtual Reality) device like a head-mounted display and a glasses-type AR (Augmented Reality) device.

### [Display Module]

FIG. 22A is a perspective view of a display module 280. The display module 280 includes a display apparatus 100C and an FPC 290. Note that the display apparatus included in the display module 280 is not limited to the display apparatus 100C and may be any of a display apparatus 100D to a display apparatus 100G described later.

The display module 280 includes a substrate 291 and a substrate 292. The display module 280 includes a display portion 281. The display portion 281 is a region of the display module 280 where an image is displayed and is a region where light from pixels provided in a pixel portion 284 described later can be perceived.

FIG. 22B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 22B. The pixel 284a includes the subpixel 110a, the subpixel 110b, and the subpixel 110c. The foregoing embodiment can be referred to for the structures of the subpixel 110a, the subpixel 110b, and the subpixel 110c and their surroundings. The plurality of subpixels can be arranged in stripe arrangement as illustrated in FIG. 22B. Alternatively, a variety of arrangement methods for light-emitting devices, such as delta arrangement or pentile arrangement, can be employed.

The pixel circuit portion 283 includes a plurality of pixel circuits 283a arranged periodically.

One pixel circuit 283a is a circuit that controls light emission from three light-emitting devices included in one pixel 284a. One pixel circuit 283a may be provided with three circuits for controlling light emission from the respective light-emitting devices. For example, the pixel circuit 283a for one light-emitting device can include at least one selection transistor, one current control transistor (driving transistor), and a capacitor. In this case, a gate signal is input to a gate of the selection transistor, and a source signal is input to one of a source and a drain thereof. With such a structure, an active-matrix display apparatus is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, power supply potential, or the like to the circuit portion 282 from the outside. In addition, an IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, and further preferably higher than or equal to 60% and lower than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a device for VR such as a head-mounted display or a glasses-type device for AR. For example, even in the case of a structure in which the display portion of the display module 280 is perceived through a lens, pixels of the extremely-high-resolution display portion 281 included in the display module 280 are not perceived when the display portion is enlarged by the lens, so that display providing a high sense of immersion can be performed. Without limitation to the above, the display module 280 can also be suitably used for an electronic device having a relatively small display portion. For example, the display module 280 can be suitably used for a display portion of a wearable electronic device such as a wrist watch.

### [Display Apparatus 100C]

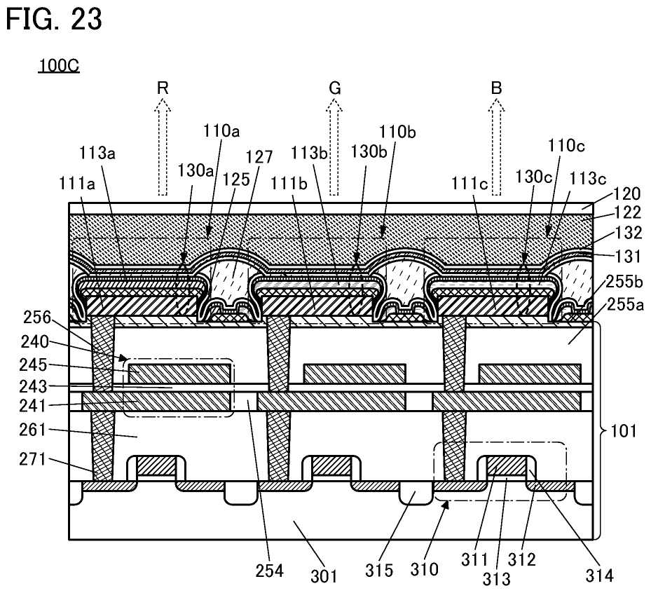

The display apparatus 100C illustrated in FIG. 23 includes a substrate 301, the subpixels 110a, 110b, and 110c, a capacitor 240, and a transistor 310. The subpixel 110a includes the light-emitting device 130a, the subpixel 110b includes the light-emitting device 130b, and the subpixel 110c includes the light-emitting device 130c.

The substrate 301 corresponds to the substrate 291 in FIG. 22A and FIG. 22B. A stacked-layer structure including the substrate 301 and the components thereover up to an insulating layer 255b corresponds to the layer 101 including transistors in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311 and functions as an insulating layer.

In addition, an element isolation layer 315 is provided between two adjacent transistors 310 to be embedded in the substrate 301.

Furthermore, an insulating layer 261 is provided to cover the transistor 310, and the capacitor 240 is provided over the insulating layer 261.

The capacitor 240 includes a conductive layer 241, a conductive layer 245, and an insulating layer 243 between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of a source and a drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240. The insulating layer 255b is provided over the insulating layer 255a. The light-emitting devices 130a, 130b, and 130c and the like are provided over the insulating layer 255b. This embodiment illustrates an example in which the light-emitting devices 130a, 130b, and 130c have the stacked-layer structure illustrated in FIG. 1B. The side surface of the pixel electrode 111 includes a region directly in contact with the insulating layer 125 and a region directly in contact with the first layer 112 in some cases. Furthermore, the first layer 112 is desirably disconnected between the adjacent pixel electrodes. The protective layer 131 is provided over the light-emitting devices 130a, 130b, and 130c. The protective layer 132 is provided over the protective layer 131, and the substrate 120 is bonded above the protective layer 132 with the resin layer 122. Embodiment 1 can be referred to for details of the light-emitting devices and the components thereover up to the substrate 120. The substrate 120 corresponds to the substrate 292 in FIG. 22A.

As each of the insulating layers 255a and 255b, a variety of inorganic insulating films such as an oxide insulating film, a nitride insulating film, an oxynitride insulating film, and a nitride oxide insulating film can be suitably used. As the insulating layer 255a, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as the insulating layer 255a and a silicon nitride film be used as the insulating layer 255b. The insulating layer 255b preferably has a function of an etching protective film. Alternatively, a nitride insulating film or a nitride oxide insulating film may be used as the insulating layer 255a, and an oxide insulating film or an oxynitride insulating film may be used as the insulating layer 255b. Although this embodiment illustrates an example in which a depressed portion is provided in the insulating layer 255b, a depressed portion is not necessarily provided in the insulating layer 255b.

The pixel electrode of the light-emitting device is electrically connected to one of the source and the drain of the transistor 310 through a plug 256 embedded in the insulating layers 255a and 255b, the conductive layer 241 embedded in the insulating layer 254, and the plug 271 embedded in the insulating layer 261. The top surface of the insulating layer 255b and the top surface of the plug 256 are level or substantially level with each other. A variety of conductive materials can be used for the plugs.

### [Display Apparatus 100D]

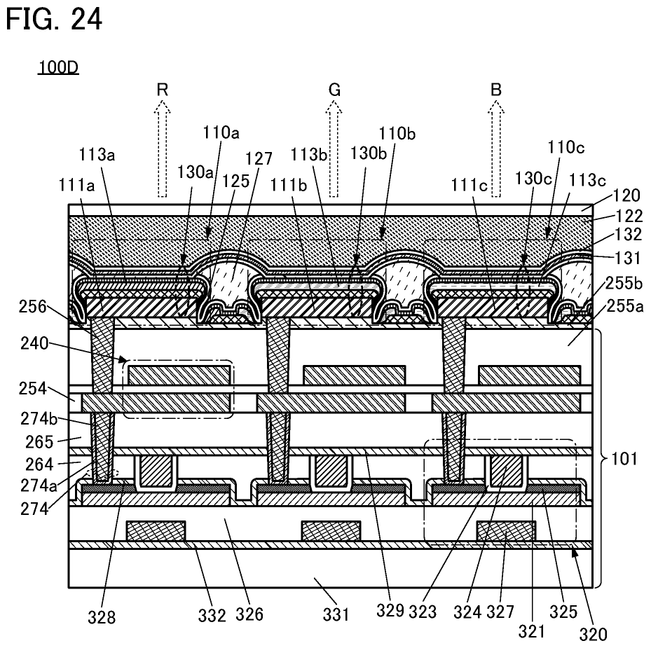

The display apparatus 100D illustrated in FIG. 24 differs from the display apparatus 100C mainly in a structure of a transistor. Note that portions similar to those of the display apparatus 100C are not described in some cases.

A transistor 320 is a transistor (OS transistor) in which a metal oxide (also referred to as an oxide semiconductor) is used in a semiconductor layer in which a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 22A and FIG. 22B. A stacked-layer structure including the substrate 331 and components thereover up to the insulating layer 255b corresponds to the layer 101 including transistors in Embodiment 1. As the substrate 331, an insulating substrate or a semiconductor substrate can be used.

An insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, it is possible to use, for example, a film in which hydrogen or oxygen is less likely to diffuse than in a silicon oxide film, such as an aluminum oxide film, a hafnium oxide film, or a silicon nitride film.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. For at least part of the insulating layer 326 that is in contact with the semiconductor layer 321, an oxide insulating film such as a silicon oxide film is preferably used. The top surface of the insulating layer 326 is preferably planarized.

The semiconductor layer 321 is provided over the insulating layer 326. The semiconductor layer 321 preferably includes a film of a metal oxide exhibiting semiconductor characteristics (also referred to as an oxide semiconductor). The material that can be suitably used for the semiconductor layer 321 will be described in detail later.

The pair of conductive layers 325 is provided over and in contact with the semiconductor layer 321, and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 or the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that their heights are equal to or substantially equal to each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 or the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers the side surface of an opening in the insulating layer 265, the insulating layer 329, the insulating layer 264, and the insulating layer 328 and part of the top surface of the conductive layer 325, and a conductive layer 274b in contact with the top surface of the conductive layer 274a. In this case, a conductive material in which hydrogen and oxygen are unlikely to diffuse is preferably used for the conductive layer 274a.

A structure including the insulating layer 254 and components thereover up to the substrate 120 in the display apparatus 100D is similar to that of the display apparatus 100C.

### [Display Apparatus 100E]

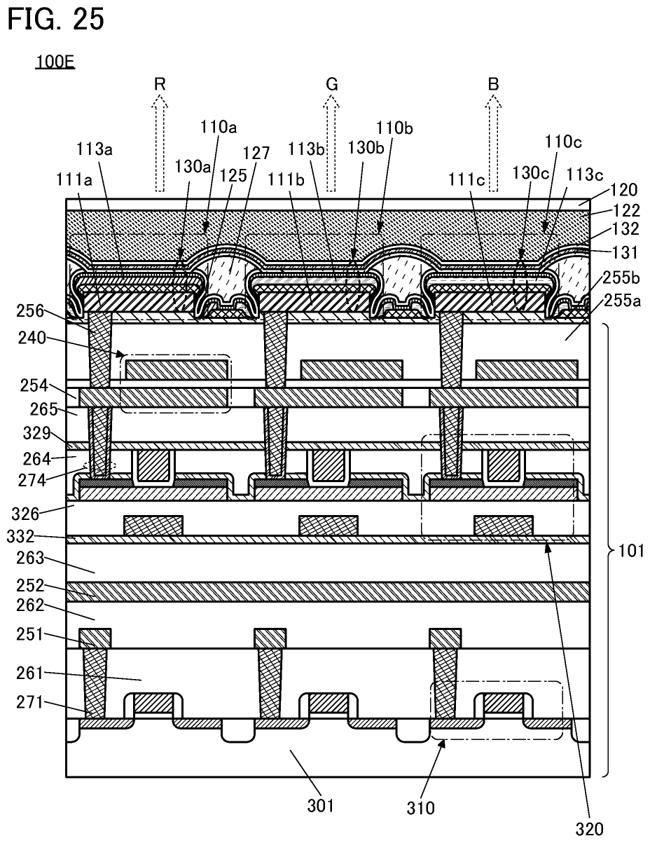

A display apparatus 100E illustrated in FIG. 25 has a structure in which the transistor 310 whose channel is formed in the substrate 301 and the transistor 320 including a metal oxide in the semiconductor layer in which the channel is formed are stacked. Note that portions similar to those of the display apparatuses 100C and 100D are not described in some cases.

The insulating layer 261 is provided to cover the transistor 310, and a conductive layer 251 is provided over the insulating layer 261. In addition, an insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in a pixel circuit. The transistor 310 can also be used as a transistor included in a pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit or the like can be formed directly under the light-emitting device; thus, the display apparatus can be downsized as compared with the case where the driver circuit is provided around a display region.

### [Display Apparatus 100F]

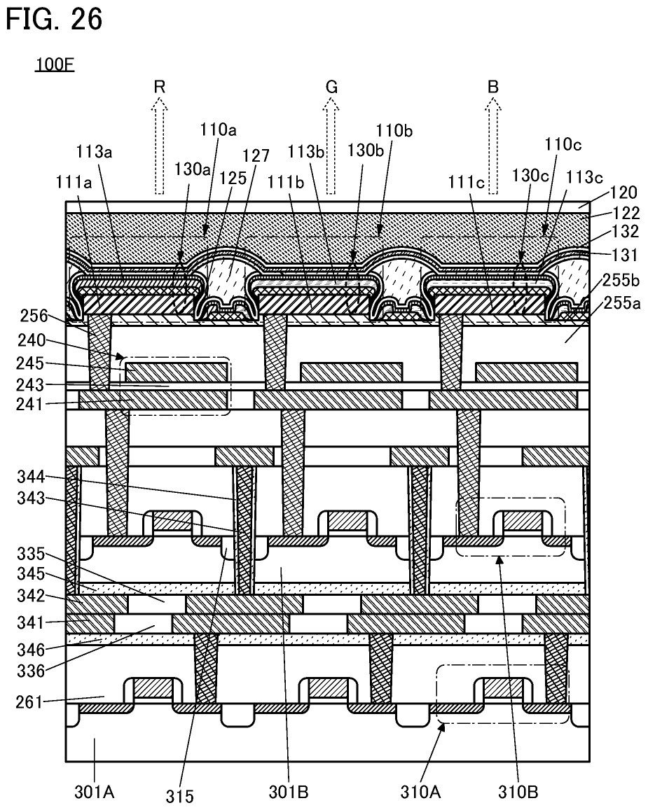

A display apparatus 100F illustrated in FIG. 26 has a structure in which a transistor 310A and a transistor 310B in each of which a channel is formed in a semiconductor substrate are stacked.

The display apparatus 100F has a structure in which a substrate 301B provided with the transistor 310B, the capacitor 240, and the light-emitting devices is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. As the insulating layers 345 and 346, an inorganic insulating film that can be used as the protective layers 131 and 132 or the insulating layer 332 can be used.

The substrate 301B is provided with a plug 343 that penetrates the substrate 301B and the insulating layer 345. An insulating layer 344 is preferably provided to cover the side surface of the plug 343. The insulating layer 344 is an insulating layer functioning as a protective layer and can inhibit diffusion of impurities into the substrate 301B. As the insulating layer 344, an inorganic insulating film that can be used as the protective layers 131 and 132 or the insulating layer 332 can be used.

A conductive layer 342 is provided under the insulating layer 345 on the rear surface of the substrate 301B (a surface opposite to the substrate 120). The conductive layer 342 is preferably provided to be embedded in the insulating layer 335. The bottom surfaces of the conductive layer 342 and the insulating layer 335 are preferably planarized. Here, the conductive layer 342 is electrically connected to the plug 343.

A conductive layer 341 is provided over the insulating layer 346 over the substrate 301A. The conductive layer 341 is preferably provided to be embedded in the insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

For the conductive layer 341 and the conductive layer 342, the same conductive material is preferably used. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-copper) direct bonding (a technique for achieving electrical continuity by connecting Cu (copper) pads).

### [Display Apparatus 100G]

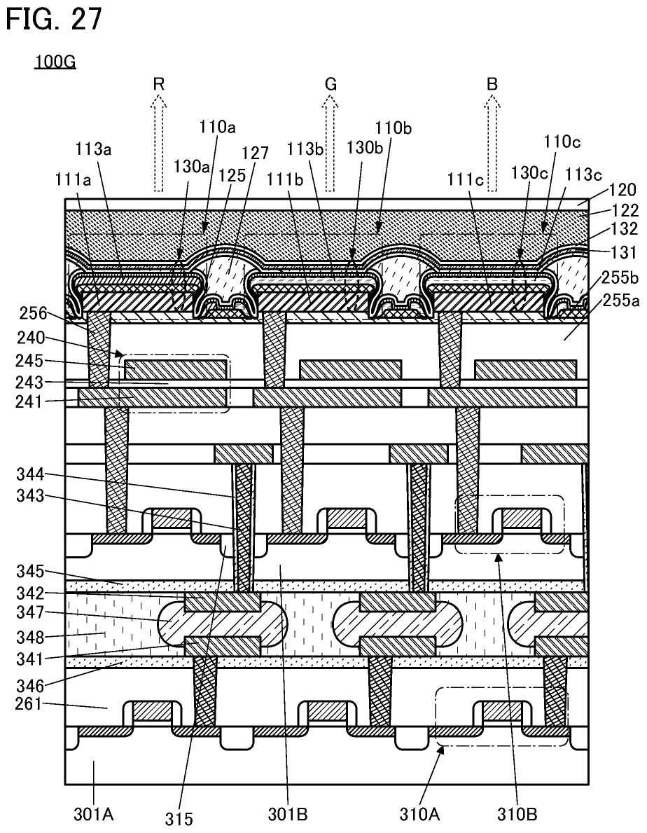

Although FIG. 26 illustrates an example in which Cu—Cu direct bonding is used to bond the conductive layer 341 and the conductive layer 342, the present invention is not limited thereto. As illustrated in FIG. 27, the conductive layer 341 and the conductive layer 342 may be bonded to each other through a bump 347 in a display apparatus 100G.

As illustrated in FIG. 27, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

This embodiment can be combined with the other embodiments as appropriate.

### Embodiment 5

In this embodiment, a structure example of a transistor that can be used in the display apparatus of one embodiment of the present invention is described. Specifically, the case of using a transistor containing silicon as a semiconductor in which a channel is formed is described.

One embodiment of the present invention is a display apparatus including a light-emitting device and a pixel circuit. For example, the display apparatus includes three kinds of subpixels that emit light of red (R), green (G), and blue (B), whereby a full-color display apparatus can be achieved.

Transistors containing silicon in their semiconductor layers in which a channel is formed are preferably used as all transistors included in the pixel circuit for driving the light-emitting device. As silicon, single crystal silicon (single crystal Si), polycrystalline silicon, amorphous silicon, and the like can be given. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of transistors containing silicon such as LTPS transistors, a circuit required to be driven at a high frequency (e.g., a source driver circuit) can be formed on the same substrate as a display portion. Thus, external circuits mounted on the display apparatus can be simplified, and costs of parts and mounting costs can be reduced.

It is preferable to use a transistor including a metal oxide (hereinafter also referred to as an oxide semiconductor) in a semiconductor in which a channel is formed (such transistor is hereinafter also referred to as an OS transistor) as at least one of the transistors included in the pixel circuit. An OS transistor has extremely higher field-effect mobility than a transistor using amorphous silicon. In addition, the OS transistor has an extremely low leakage current between a source and a drain in an off state (hereinafter also referred to as off-state current), and charge accumulated in a capacitor that is connected in series to the transistor can be retained for a long period. Furthermore, power consumption of the display apparatus can be reduced with an OS transistor.

When an LTPS transistor is used as one or more of the transistors included in the pixel circuit and an OS transistor is used as the rest, the display apparatus can have low power consumption and high driving capability. As a more favorable example, it is preferable to use an OS transistor as a transistor or the like functioning as a switch for controlling electrical continuity between wirings and an LTPS transistor as a transistor or the like for controlling a current. Note that a structure in which an LTPS transistor and an OS transistor are combined is referred to as LTPO in some cases. LTPO enables the display panel to have low power consumption and high driving capability.

For example, one of the transistors included in the pixel circuit functions as a transistor for controlling a current flowing through the light-emitting device and can be referred to as a driving transistor. One of a source and a drain of the driving transistor is electrically connected to a pixel electrode of the light-emitting device. An LTPS transistor is preferably used as the driving transistor. In that case, the amount of current flowing through the light-emitting device can be increased in the pixel circuit.

Meanwhile, another transistor provided in the pixel circuit functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

More specific structure examples are described below with reference to drawings.

### Structure Example 2 of Display Apparatus

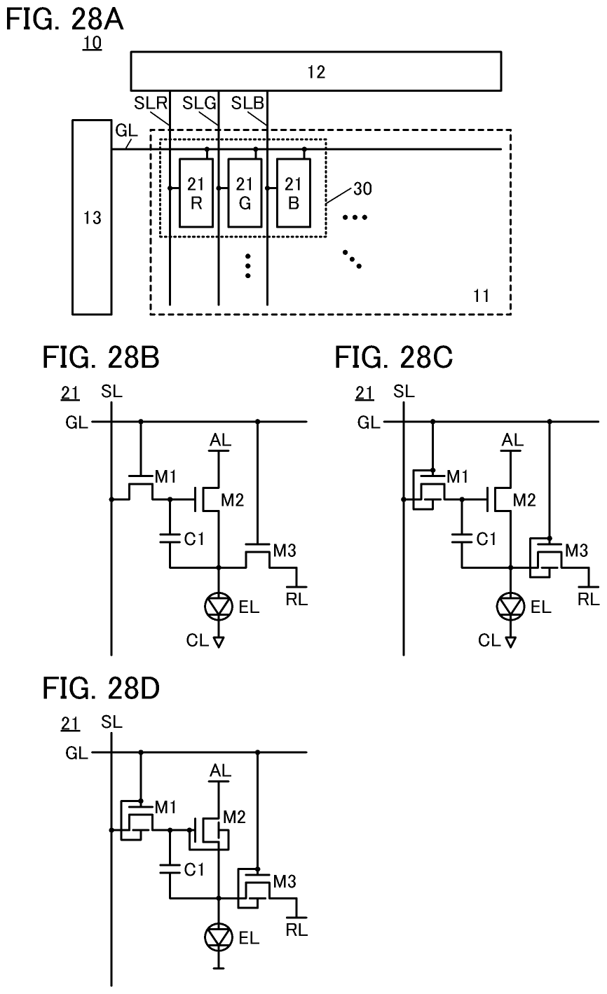

FIG. 28A illustrates a block diagram of a display apparatus 10. The display apparatus includes a display portion 11, a driver circuit portion 12, a driver circuit portion 13, and the like.

The display portion 11 includes a plurality of pixels 30 arranged in a matrix. The pixel includes a subpixel 21R, a subpixel 21G, and a subpixel 21B. The subpixel 21R, the subpixel 21G, and the subpixel 21B each include a light-emitting device functioning as a display device.

The pixel 30 is electrically connected to a wiring GL, a wiring SLR, a wiring SLG, and a wiring SLB. The wiring SLR, the wiring SLG, and the wiring SLB are electrically connected to the driver circuit portion 12. The wiring GL is electrically connected to the driver circuit portion 13. The driver circuit portion 12 functions as a source line driver circuit (also referred to as a source driver), and the driver circuit portion 13 functions as a gate line driver circuit (also referred to as a gate driver). The wiring GL functions as a gate line, and the wiring SLR, the wiring SLG, and the wiring SLB function as source lines.

The subpixel 21R includes a light-emitting device that emits red light. The subpixel 21G includes a light-emitting device that emits green light. The subpixel 21B includes a light-emitting device that emits blue light. Thus, the display apparatus 10 can perform full-color display. The pixel 30 may include a subpixel that emits light of another color. For example, the pixel 30 may include, in addition to the three subpixels, a subpixel that emits white light, a subpixel that emits yellow light, or the like.

The wiring GL is electrically connected to the subpixel 21R, the subpixel 21G, and the subpixel 21B arranged in a row direction (an extending direction of the wiring GL). The wiring SLR, the wiring SLG, and the wiring SLB are electrically connected to the subpixels 21R, the subpixels 21G, and the subpixels 21B (not illustrated) arranged in a column direction (an extending direction of the wiring SLR and the like), respectively.

### Structure Example of Pixel Circuit

FIG. 28B illustrates an example of a circuit diagram of a pixel 21 that can be used as the subpixel 21R, the subpixel 21G, and the subpixel 21B. The pixel 21 includes a transistor M1, a transistor M2, a transistor M3, a capacitor C1, and a light-emitting device EL. The wiring GL and the wiring SL are electrically connected to the pixel 21. The wiring SL corresponds to any of the wiring SLR, the wiring SLG, and the wiring SLB illustrated in FIG. 28A.

A gate of the transistor M1 is electrically connected to the wiring GL, one of a source and a drain of the transistor M1 is electrically connected to the wiring SL, and the other of the source and the drain of the transistor M1 is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device EL is electrically connected to a wiring CL.

A data potential D is supplied to the wiring SL. A selection signal is supplied to the wiring GL. The selection signal includes a potential for turning on a transistor and a potential for turning off a transistor.

A reset potential is supplied to the wiring RL. An anode potential is supplied to the wiring AL. A cathode potential is supplied to the wiring CL. In the pixel 21, the anode potential is a potential higher than the cathode potential. The reset potential supplied to the wiring RL can be set such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. For example, the transistor M2 functions as a transistor that controls a current flowing through the light-emitting device EL. For example, it can be regarded that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In that case, an LTPS transistor can be used as at least one of a plurality of transistors included in the driver circuit portion 12 and a plurality of transistors included in the driver circuit portion 13, and OS transistors can be used as the other transistors. For example, OS transistors can be used as the transistors provided in the display portion 11, and LTPS transistors can be used as the transistors provided in the driver circuit portion 12 and the driver circuit portion 13.

As the OS transistor, a transistor including an oxide semiconductor in a semiconductor layer in which a channel is formed can be used. The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Further alternatively, it is preferable to use an oxide containing indium, gallium, tin, and zinc.

A transistor using an oxide semiconductor having a wider band gap and a lower carrier density than silicon can achieve an extremely low off-state current. Thus, such a low off-state current enables retention of charge accumulated in a capacitor that is series-connected to the transistor for a long period. Thus, it is particularly preferable to use a transistor including an oxide semiconductor as the transistor M1 and the transistor M3 each of which is connected in series to the capacitor C1. The use of the transistor including an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long period without rewriting data in the pixel 21.

Although n-channel transistors are shown as the transistors in FIG. 28B, p-channel transistors can be used.

The transistors included in the pixel 21 are preferably arranged over the same substrate.

Transistors each including a pair of gates overlapping with each other with a semiconductor layer therebetween can be used as the transistors included in the pixel 21.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 21 illustrated in FIG. 28C is an example in which a transistor including a pair of gates is used as each of the transistor M1 and the transistor M3. In each of the transistor M1 and the transistor M3, the pair of gates are electrically connected to each other. Such a structure can shorten the time taken for writing data to the pixel 21.

The pixel 21 illustrated in FIG. 28D is an example in which a transistor including a pair of gates is used as the transistor M2 in addition to the transistor M1 and the transistor M3. A pair of gates of the transistor M2 are electrically connected to each other. When such a transistor is used as the transistor M2, the saturation characteristics are improved, whereby emission luminance of the light-emitting device EL can be controlled easily and the display quality can be increased.

### Structure Example of Transistor

Cross-sectional structure examples of a transistor that can be used in the display apparatus are described below.

### Structure Example 1

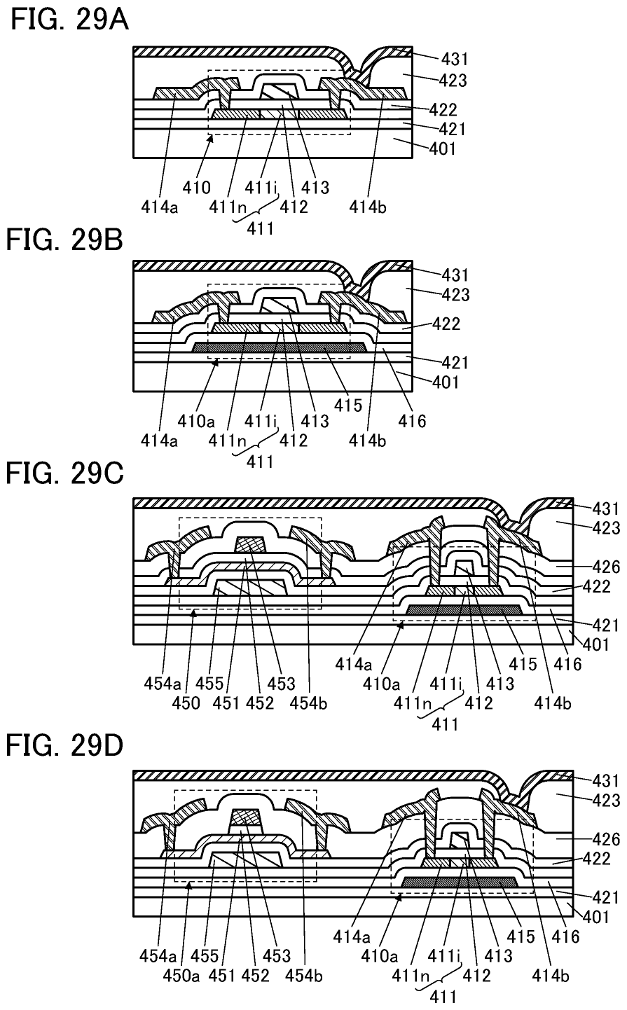

FIG. 29A is a cross-sectional view including a transistor 410.

The transistor 410 is a transistor provided over a substrate 401 and containing polycrystalline silicon in its semiconductor layer. For example, the transistor 410 corresponds to the transistor M2 in the pixel 21. In other words, FIG. 29A illustrates an example in which one of a source and a drain of the transistor 410 is electrically connected to a conductive layer 431 of the light-emitting device.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can contain a metal oxide exhibiting semiconductor characteristics (also referred to as an oxide semiconductor). In this case, the transistor 410 can be referred to as an OS transistor.

The low-resistance regions 411n are regions containing an impurity element. For example, in the case where the transistor 410 is an n-channel transistor, phosphorus, arsenic, or the like is added to the low-resistance regions 411n. Meanwhile, in the case where the transistor 410 is a p-channel transistor, boron, aluminum, or the like is added to the low-resistance regions 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are each electrically connected to the low-resistance region 411n in an opening portion provided in the insulating layer 422 and the insulating layer 412. Part of the conductive layer 414a functions as one of a source electrode and a drain electrode, and part of the conductive layer 414b functions as the other of the source electrode and the drain electrode. An insulating layer 423 is provided to cover the conductive layer 414a, the conductive layer 414b, and the insulating layer 422.

The conductive layer 431 functioning as a pixel electrode is provided over the insulating layer 423. The conductive layer 431 is provided over the insulating layer 423 and is electrically connected to the conductive layer 414b through an opening provided in the insulating layer 423. Although not illustrated here, an EL layer and a common electrode can be stacked over the conductive layer 431.

### Structure Example 2

FIG. 29B illustrates a transistor 410a including a pair of gate electrodes. The transistor 410a illustrated in FIG. 29B is different from FIG. 29A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 29B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case where LTPS transistors are used as all of the transistors included in the pixel 21, the transistor 410 illustrated in FIG. 29A as an example or the transistor 410a illustrated in FIG. 29B as an example can be used. In this case, the transistors 410a may be used as all of the transistors included in the pixel 21, the transistors 410 may be used as all of the transistors, or a combination of the transistors 410a and the transistors 410 may be used.

### Structure Example 3

Described below is an example of a structure including both a transistor containing silicon in its semiconductor layer and a transistor including a metal oxide in its semiconductor laver.

FIG. 29C is a schematic cross-sectional view including the transistor 410a and a transistor 450.

Structure example 1 described above can be referred to for the transistor 410a. Although an example using the transistor 410a is illustrated here, a structure including the transistor 410 and the transistor 450 may be employed, or a structure including all the transistor 410, the transistor 410a, and the transistor 450 may be employed.

The transistor 450 is a transistor including a metal oxide in its semiconductor layer. The structure illustrated in FIG. 29C illustrates an example in which the transistor 450 corresponds to the transistor M1 and the transistor 410a corresponds to the transistor M2 in the pixel 21. That is, FIG. 29C illustrates an example in which one of a source and a drain of the transistor 410a is electrically connected to the conductive layer 431.

Moreover, FIG. 29C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in opening portions provided in the insulating layer 426 and the insulating layer 452. Part of the conductive layer 454a functions as one of a source electrode and a drain electrode and part of the conductive layer 454b functions as the other of the source electrode and the drain electrode. The insulating layer 423 is provided to cover the conductive layer 454a, the conductive layer 454b, and the insulating layer 426.

Here, the conductive layer 414a and the conductive layer 414b that are electrically connected to the transistor 410a are preferably formed by processing the same conductive film as the conductive layer 454a and the conductive layer 454b. FIG. 29C illustrates a structure in which the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This is preferable because the manufacturing process can be simplified.

Moreover, the conductive layer 413 functioning as a first gate electrode of the transistor 410a and the conductive layer 455 functioning as a second gate electrode of the transistor 450 are preferably formed by processing the same conductive film. FIG. 29C illustrates a structure in which the conductive layer 413 and the conductive layer 455 are formed on the same plane (i.e., in contact with the top surface of the insulating layer 412) and contain the same metal element. This is preferable because the manufacturing process can be simplified.

Although the insulating layer 452 functioning as the first gate insulating layer of the transistor 450 covers an end portion of the semiconductor layer 451 in the structure in FIG. 29C, the insulating layer 452 may be processed to have the same or substantially the same top surface shape as that of the conductive layer 453 as in a transistor 450a illustrated in FIG. 29D.

Note that in this specification and the like, the expression “top surface shapes are substantially the same” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is positioned on an inner side of the lower layer or the upper layer is positioned on an outer side of the lower layer: such a case is also represented by the expression “top surface shapes are the same”.

Although the example in which the transistor 410a corresponds to the transistor M2 and is electrically connected to the pixel electrode is shown here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

This embodiment can be combined with the other embodiments as appropriate.

### Embodiment 6

In this embodiment, a metal oxide (also referred to as an oxide semiconductor) that can be used in the OS transistor described in the above embodiment is described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a chemical vapor deposition (CVD) method such as a metal organic chemical vapor deposition (MOCVD) method, an atomic layer deposition method, or the like.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method.

For example, the XRD spectrum of a quartz glass substrate shows a peak with a substantially bilaterally symmetrical shape. On the other hand, the peak of the XRD spectrum of the IGZO film having a crystal structure has a bilaterally asymmetrical shape. The asymmetrical peak of the XRD spectrum clearly shows the existence of crystal in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film deposited at room temperature. Thus, it is suggested that the IGZO film deposited at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from the one described above when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement, t. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions described above is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter an In layer) and a layer containing the element M, zinc (Zn), and oxygen (hereinafter an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction described above, a lattice arrangement in the crystal region is basically a hexagonal lattice arrangement: however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, In—Zn oxide and In—Ga—Zn oxide are suitable because they can inhibit generation of a crystal grain boundary as compared with In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in a nanobeam electron diffraction pattern of the nc-OS film obtained using an electron beam with a probe diameter nearly equal to or smaller than the diameter of a nanocrystal (e.g., 1 nm or larger and 30 nm or smaller).

[a-like OS]

The a-like OS is an oxide semiconductor having a structure between those of the nc-OS and the amorphous oxide semiconductor. The a-like OS contains a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in In—Ga—Zn oxide are denoted by [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. For example, the first region has higher [In] and lower [Ga] than the second region. Moreover, the second region has higher [Ga] and lower [In] than the first region.

Specifically, the first region contains indium oxide, indium zinc oxide, or the like as its main component. The second region contains gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and less than 30%, and further preferably higher than or equal to 0% and less than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide like a cloud, high field-effect mobility (u) can be achieved.

The second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material: as a whole, the CAC-OS has a function of a semiconductor. Separation of the conducting function and the insulating function can maximize each function. Accordingly, when the CAC-OS is used for a transistor, a high on-state current (Ion), high field-effect mobility (u), and excellent switching operation can be achieved.

A transistor using the CAC-OS has high reliability. Thus, the CAC-OS is most suitable for a variety of semiconductor devices such as display apparatuses.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1× 10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2× 10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy sometimes generates an electron serving as a carrier. Furthermore, bonding of part of hydrogen to oxygen bonded to a metal atom sometimes causes generation of an electron serving as a carrier. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, and still further preferably lower than 1× 10¹⁸ atoms/cm³.

When an oxide semiconductor with sufficiently reduced impurities is used for the channel formation region of the transistor, stable electrical characteristics can be given.

This embodiment can be combined with the other embodiments as appropriate.

### Embodiment 7

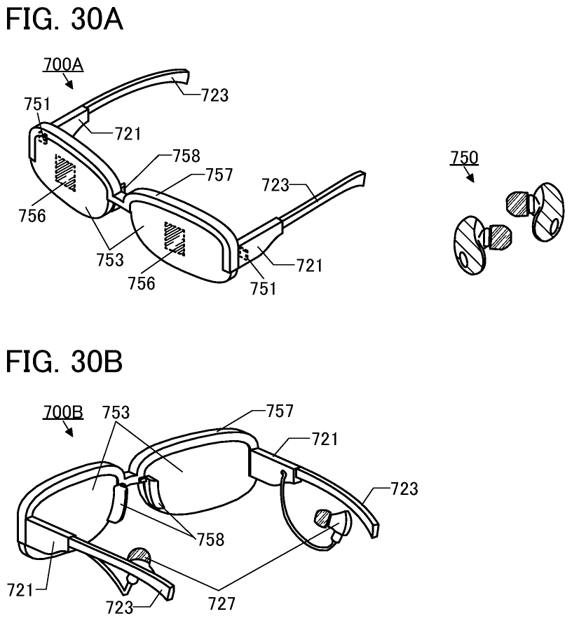

In this embodiment, electronic devices of one embodiment of the present invention are described with reference to FIG. 30A to FIG. 34G.

An electronic device of this embodiment is provided with the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of electronic devices include a digital camera, a digital video camera, a digital photo frame, a mobile phone, a portable game console, a portable information terminal, and an audio reproducing device in addition to electronic devices with a relatively large screen, such as a television device, a desktop or laptop personal computer, a monitor of a computer or the like, digital signage, and a large game machine such as a pachinko machine.

In particular, a display apparatus of one embodiment of the present invention can have a high resolution, and thus can be favorably used for an electronic device having a relatively small display portion. Examples of such an electronic device include a watch-type or a bracelet-type information terminal device (wearable device), and a wearable device capable of being worn on a head, such as a device for VR such as a head-mounted display, a glasses-type device for AR, and a device for MR.

The definition of the display apparatus of one embodiment of the present invention is preferably as high as HD (number of pixels: 1280×720), FHD (number of pixels: 1920×1080), WQHD (number of pixels: 2560)×1440), WQXGA (number of pixels: 2560)×1600), 4K (number of pixels: 3840× 2160), or 8K (number of pixels: 7680×4320). In particular, the definition is preferably 4K, 8K, or higher. Furthermore, the pixel density (resolution) of the display apparatus of one embodiment of the present invention is preferably higher than or equal to 100 ppi, preferably higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, and yet further preferably higher than or equal to 7000 ppi. With the use of such a display apparatus with one or both of high definition and high resolution, the electronic device can have higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

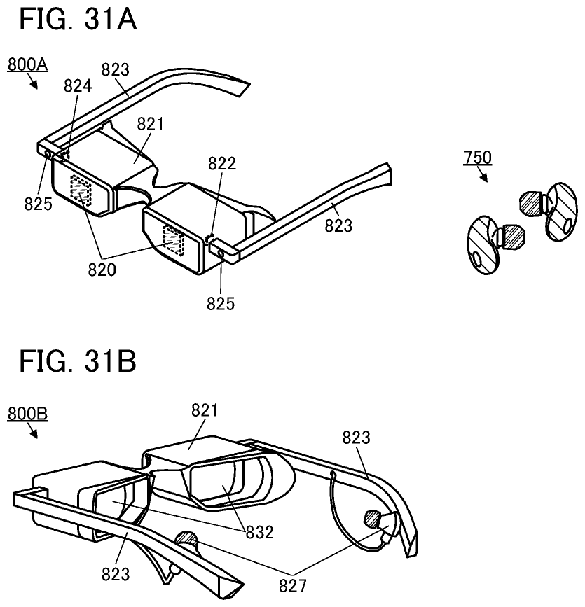

Examples of head-mounted wearable devices are described with reference to FIG. 30A, FIG. 30B, FIG. 31A, and FIG. 31B. These wearable devices have one or both of a function of displaying AR contents and a function of displaying VR contents. Note that these wearable devices may have a function of displaying SR(SUBSTITUTIONAL Reality) or MR (Mixed Reality) contents, in addition to AR and VR contents. The electronic device having a function of displaying contents of AR, VR, SR, MR, or the like enables the user to reach a higher level of immersion.

An electronic device 700A illustrated in FIG. 30A and an electronic device 700B illustrated in FIG. 30B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panel 751. Thus, the electronic device can perform display with extremely high resolution.

The electronic device 700A and the electronic device 700B can each project an image displayed on the display panel 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display region 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward or fast rewind can be executed by a slide operation. The touch sensor module is provided in each of the two housings 721, whereby the range of the operation can be increased.

A variety of touch sensors can be applied to the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 31A and an electronic device 800B illustrated in FIG. 31B each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with extremely high resolution. This enables a user to feel high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 31A or the like illustrates an example in which the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example of including the image capturing portion 825 is described here, a range sensor (hereinafter also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be applied to any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 30A has a function of transmitting information to the earphones 750 with the wireless communication function. As another example, the electronic device 800A illustrated in FIG. 31A has a function of transmitting information to the earphones 750 with the wireless communication function.

The electronic device may include an earphone portion. The electronic device 700B illustrated in FIG. 30B includes earphone portions 727. For example, a structure in which the earphone portions 727 and the control portion are connected to each other by wire may be employed. Part of a wiring that connects the earphone portions 727 and the control portion may be positioned inside the housing 721 or the wearing portion 723.

Similarly, the electronic device 800B illustrated in FIG. 31B includes earphone portions 827. For example, a structure in which the earphone portions 827 and the control portion 824 are connected to each other by wire may be employed. Part of a wiring that connects the earphone portions 827 and the control portion 824 may be positioned inside the housing 821 or the wearing portion 823. The earphone portions 827 and the wearing portion 823 may include magnets. This is preferable because the earphone portions 827 can be fixed to the wearing portion 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

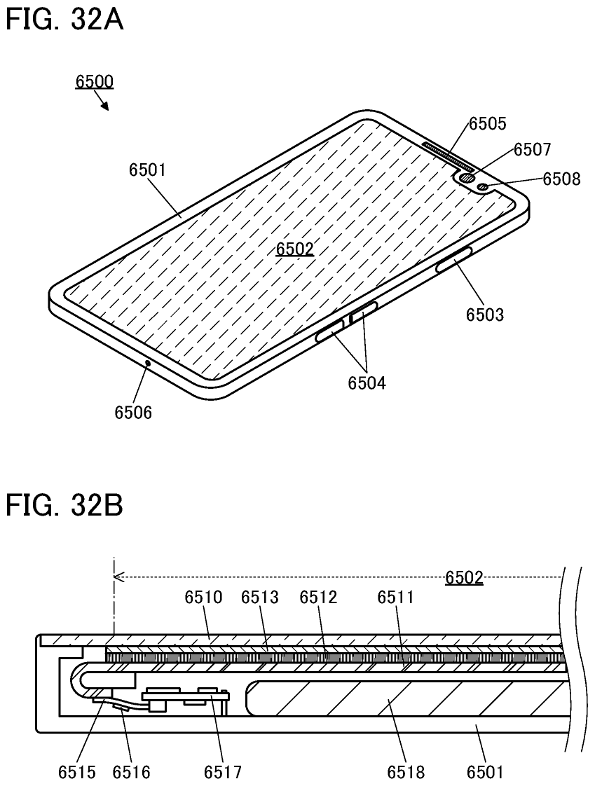

An electronic device 6500 illustrated in FIG. 32A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 32B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of the pixel portion, whereby an electronic device with a narrow bezel can be achieved.

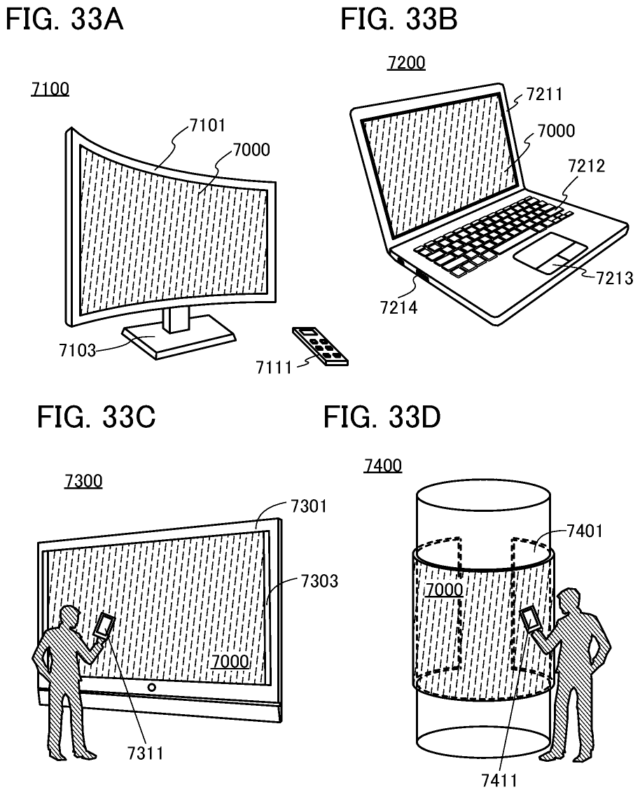

FIG. 33A illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 33A can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be operated and images displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 33B illustrates an example of a laptop personal computer. The laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 33C and FIG. 33D illustrate examples of digital signage.

Digital signage 7300 illustrated in FIG. 33C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 33D is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in FIG. 33C and FIG. 33D.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 33C and FIG. 33D, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

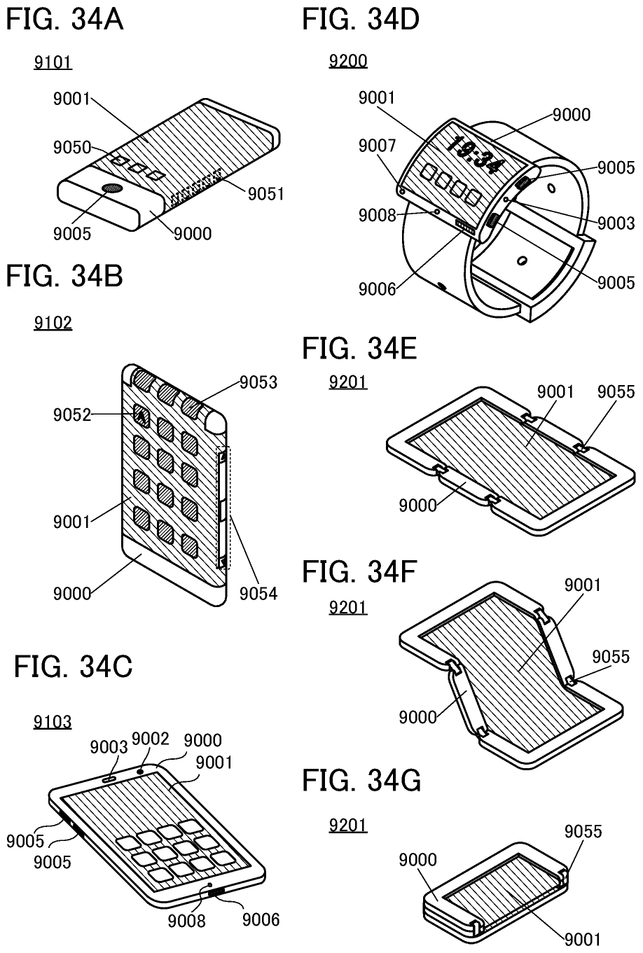

Electronic devices illustrated in FIG. 34A to FIG. 34G each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared ray's), a microphone 9008, and the like.

The electronic devices illustrated in FIG. 34A to FIG. 34G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 34A to FIG. 34G are described in detail below.

FIG. 34A is a perspective view illustrating a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters and image information on its plurality of surfaces. FIG. 34A illustrates an example in which three icons 9050 are displayed. Furthermore, information 9051 indicated by dashed rectangles can be displayed on another surface of the display portion 9001. Examples of the information 9051 include notification of reception of an e-mail, an SNS(Social Networking Service) message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 34B is a perspective view illustrating a portable information terminal 9102. The portable information terminal 9102 has a function of displaying information on three or more surfaces of the display portion 9001. Shown here is an example in which information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 34C is a perspective view of a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, the camera 9002, the microphone 9008, and the speaker 9003 on the front surface of the housing 9000: the operation keys 9005 as buttons for operation on the left side surface of the housing 9000; and the connection terminal 9006 on the bottom surface of the housing 9000.

FIG. 34D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 34E to FIG. 34G are perspective views illustrating a foldable portable information terminal 9201. FIG. 34E is a perspective view of an opened state of the portable information terminal 9201, FIG. 34G is a perspective view of a folded state thereof, and FIG. 34F is a perspective view of a state in the middle of change from one of FIG. 34E and FIG. 34G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined with the other embodiments as appropriate.

### REFERENCE NUMERALS

AL: wiring, CL: wiring, GL: wiring, RL: wiring, SL: wiring, SLB: wiring, SLG: wiring, SLR: wiring, 10: display apparatus, 11: display portion, 12: driver circuit portion, 13: driver circuit portion, 21: pixel, 21R: subpixel, 21G: subpixel, 21B: subpixel, 30: pixel, 100: display apparatus, 100A: display apparatus, 100B: display apparatus, 100C: display apparatus, 100D: display apparatus, 100E: display apparatus, 100F: display apparatus, 100G: display apparatus, 101: layer, 103: EL layer, 103a: EL layer, 103b: EL layer, 103c: EL layer, 110: pixel, 110a: subpixel, 110b: subpixel, 110c: subpixel, 111A: conductive film, 111a: pixel electrode, 111b: pixel electrode, 111c: pixel electrode, 112: first layer, 112G: organic layer, 113: light-emitting layer, 113a: first light-emitting layer, 113b: second light-emitting layer, 113c: third light-emitting layer, 113aG: organic layer, 113bG: organic layer, 113cG: organic layer, 114: second layer, 114G: organic layer, 115: third layer, 116: common electrode, 117: light-blocking layer, 118: insulating layer, 120: substrate, 122: resin layer, 123: conductive layer, 124a: pixel, 124b: pixel, 125: insulating layer, 125A: insulating film, 126: optical adjustment layer, 126a: conductive layer, 126b: conductive layer, 126c: conductive layer, 127: insulating layer, 127A: insulating film, 128: layer, 130: light-emitting device, 130a: light-emitting device, 130b: light-emitting device, 130c: light-emitting device, 131: protective layer, 132: protective layer, 138: region, 140: connection portion, 142: adhesive layer, 151: substrate, 152: substrate, 153: insulating layer, 162: display portion, 164: circuit, 165: wiring, 166: conductive layer, 172: FPC, 173: IC, 190a: resist mask, 190b: resist mask, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 222c: conductive layer, 223: conductive layer, 225: insulating layer, 228: region, 231: semiconductor layer, 231i: channel formation region, 231n: low-resistance region, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 256: plug, 261: insulating layer, 262: insulating layer, 263: insulating layer, 264: insulating layer, 265: insulating layer, 271: plug, 274: plug, 274a: conductive layer, 274b: conductive layer, 280: display module, 281: display portion, 282: circuit portion, 283: pixel circuit portion, 283a: pixel circuit, 284: pixel portion, 284a: pixel, 285: terminal portion, 286: wiring portion, 290: FPC, 291: substrate, 292: substrate, 301: substrate, 301A: substrate, 301B: substrate, 310: transistor, 310A: transistor, 310B: transistor, 311: conductive layer, 312: low-resistance region, 313: insulating layer, 314: insulating layer, 315: element isolation layer, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 401: substrate, 410: transistor, 410a: transistor, 411: semiconductor layer, 411i: channel formation region, 411n: low-resistance region, 412: insulating layer, 413: conductive layer, 414a: conductive layer, 414b: conductive layer, 415: conductive layer, 416: insulating layer, 421: insulating layer, 422: insulating layer, 423: insulating layer, 426: insulating layer, 431: conductive layer, 450: transistor, 450a: transistor, 451: semiconductor layer, 452: insulating layer, 453: conductive layer, 454a: conductive layer, 454b: conductive layer, 455: conductive layer, 700A: electronic device, 700B: electronic device, 721: housing, 723: wearing portion, 727: earphone portion, 750: earphone, 751: display panel, 753: optical member, 756: display region, 757: frame, 758: nose pad, 772: lower electrode, 785: layer, 786: EL layer, 786a: EL layer, 786b: EL layer, 788: upper electrode, 800A: electronic device, 800B: electronic device, 820: display portion, 821: housing, 822: communication portion, 823: wearing portion, 824: control portion, 825: image capturing portion, 827: earphone portion, 832: lens, 4411: light-emitting layer, 4412: light-emitting layer, 4413: light-emitting layer, 4420: layer, 4421: layer, 4422: layer, 4430: layer, 4431: layer, 4432: layer, 4440: charge-generation layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first light-emitting element and a second light-emitting element,
wherein the first light-emitting element and the second light-emitting element are configured to emit light of different colors,
wherein the first light-emitting element comprises a first pixel electrode, a first EL layer over the first pixel electrode, and a common electrode over the first EL layer,
wherein the second light-emitting element comprises a second pixel electrode, a second EL layer over the second pixel electrode, and the common electrode over the second EL layer,
wherein the first EL layer comprises a first layer over the first pixel electrode, and a first light-emitting layer over the first layer,
wherein the first layer comprises a hole-injection layer,
wherein an angle between a side surface of the first pixel electrode and a bottom surface of the first pixel electrode is greater than or equal to 60° and less than or equal to 140°, and
wherein a ratio T1/T2 of a thickness T1 of the first pixel electrode with respect to a thickness T2 of the first layer in a region in contact with a top surface of the first pixel electrode is greater than or equal to 0.5.

2. A display apparatus comprising:
a first insulating layer, a first light-emitting element over the first insulating layer, and a second light-emitting element over the first insulating layer,
wherein the first light-emitting element and the second light-emitting element are configured to emit light of different colors,
wherein the first light-emitting element comprises a first pixel electrode, a first EL layer over the first pixel electrode, and a common electrode over the first EL layer,
wherein the second light-emitting element comprises a second pixel electrode, a second EL layer over the second pixel electrode, and the common electrode over the second EL layer,
wherein the first EL layer comprises a first layer over the first pixel electrode, and a first light-emitting layer over the first layer,
wherein the first layer comprises a hole-injection layer,
wherein the first insulating layer comprises a depressed portion between the first pixel electrode and the second pixel electrode,
wherein an angle between a bottom surface extension line extended, in parallel to a bottom surface of the first pixel electrode, from the lowest portion of the depressed portion to a region below the first pixel electrode is greater than or equal to 60° and less than or equal to 140°, and
wherein a ratio [ET/T2] of a shortest distance ET from the bottom surface extension line to a top surface of the first pixel electrode with respect to a thickness T2 of the first layer is greater than or equal to 0.5.

3. The display apparatus according to claim 1, further comprising a second insulating layer in contact with the side surface of the first pixel electrode and a side surface of the second pixel electrode.

4. The display apparatus according to claim 3, wherein the second insulating layer contains an inorganic material.

5. The display apparatus according to claim 3, further comprising a third insulating layer between the first pixel electrode and the second pixel electrode,
wherein the third insulating layer is positioned below the common electrode.

6. The display apparatus according to claim 5, wherein the third insulating layer contains an organic material.

7. The display apparatus according to claim 5,
wherein the second EL layer comprises a second layer over the second pixel electrode, and a second light-emitting layer over the second layer,
wherein the third insulating layer is positioned placed below the common electrode between the first light-emitting element and the second light-emitting element,
wherein the second insulating layer is positioned below the third insulating layer between the first light-emitting element and the second light-emitting element,
wherein a first organic layer is positioned below the second insulating layer between the first light-emitting element and the second light-emitting element, and
wherein the first organic layer, the first layer, and the second layer comprise the same material.

8. The display apparatus according to claim 7, further comprising a second organic layer and a third organic layer over the first organic layer,
wherein the second organic layer comprises the same material as the first light-emitting layer, and
wherein the third organic layer comprises the same material as the second light-emitting layer.

9. The display apparatus according to claim 5,
wherein a top surface of the first EL layer, a top surface of the second EL layer, and a top surface of the third insulating layer each comprise a region in contact with the common electrode.

10. The display apparatus according to claim 9, wherein the first layer comprises a hole-transport layer over the hole-injection layer.

11. The display apparatus according to claim 9, wherein the first EL layer comprises an electron-transport layer over the first light-emitting layer.

12. The display apparatus according to claim 11, wherein the first EL layer comprises an electron-injection layer between the electron-transport layer and the common electrode.
